(19) United States
(12) Patent Application Publication
(10) Pub. No.: US 2013/0183816 A1
(43) Pub. Date: Jul. 18, 2013

(54) METHOD OF MANUFACTURING SEMICONDUCTOR DEVICE

(71) Applicant: Shuichi TANIGUCHI, Yokohama-shi (JP)

(72) Inventor: Shuichi TANIGUCHI, Yokohama-shi (JP)

(21) Appl. No.: 13/617,380

(22) Filed: Sep. 14, 2012

(30) Foreign Application Priority Data
Jan. 12, 2012 (JP) 2012-003979

(51) Int. Cl. H01L 21/425; H01L 21/22

(52) U.S. Cl. 438/514; 438/542; 257/E21.473; 257/E21.135

(57) ABSTRACT

According to one embodiment, a method of manufacturing a semiconductor device is provided. In the method of manufacturing a semiconductor device, a first layer containing Si is formed on a semiconductor substrate. An impurity region and a non-impurity region are formed in the first layer by selectively diffusing an impurity into the first layer. A second layer containing a metal material is formed on the first layer. The metal material is diffused into the non-impurity region by annealing the second layer.

### CROSS-REFERENCE TO RELATED APPLICATIONS

This application is based upon and claims the benefit of priority from Japanese Patent Application No. 2012-003979, filed Jan. 12, 2012, the entire contents of which are incorporated herein by reference.

### FIELD

Embodiments described herein relate generally to a method of manufacturing a semiconductor device.

BACKGROUND

In recent years, a resistance change nonvolatile memory that uses, as a memory element, not a three-terminal element such as a floating gate memory element or a MONOS memory element but a two-terminal element, like a resistance random access memory (ReRAM), has recently been proposed as a next-generation bulk memory that replaces a conventional NAND flash memory. In this memory, a memory element is arranged at the intersection of two independent conductive lines. The resistance values (for example, two values of high resistance (off) and low resistance (on)) of the memory element are programmed by a current or a voltage, thereby storing data.

There is known an ReRAM of a type that changes the resistance by, for example, allowing a metal filament to precipitate in a high-resistance layer between electrodes. Especially, a memory having a high-resistance layer made of amorphous silicon (a-Si) has received a great deal of attention because of its high switching probability and potential for microfabrication. In this memory, the metal of the electrode forms a filament in the a-Si layer. A memory function is obtained by a change in the resistance caused by the filament. An example of the metal material to form a filament in the a-Si layer is silver (Ag).

When Ag is used as an electrode, processing the electrode is performed by reactive ion etching (RIE) or the like. However, a low-volatile metal material such as Ag is difficult to process. For this reason, when processing is done by RIE or the like, processing failures such as electrode shape abnormalities and dimensional variations occur. For example, the electrodes are tapered because vertical processing of electrodes is impossible. As described above, there is a demand for processing a metal material, which is hard to process, into a desired shape.

### BRIEF DESCRIPTION OF THE DRAWINGS

FIG. 1 is a perspective views showing an example of the arrangement of a memory cell array according to the first embodiment;

FIGS. 2A and 2B are sectional views showing the structure of a memory cell according to the first embodiment;

FIGS. 3A and 3B are views showing an example of a resistance change in a resistance change layer according to the first embodiment;

FIGS. 4A, 4B, 5A, 5B, 6A, 6B, 7A, 7B, 8A, 8B, 9A, 9B, 10A, 10B, 11A, 11B, 12A, and 12B are sectional views showing steps in the manufacture of the memory cell according to the first embodiment;

FIG. 13 is a graph showing Ag diffusion into an a-Si layer in an annealing process according to the first embodiment;

FIG. 14 is a graph showing Ag diffusion into an a-Si layer in an annealing process according to Comparative Example 1;

FIG. 15 is a graph showing Ag diffusion into an a-Si layer in an annealing process according to

Comparative Example 2;

FIG. 16 is a graph showing Ag diffusion with respect to the O concentration in the a-Si layer in the annealing process;

FIGS. 17A, 17B, 18A, 18B, 19A, and 19B are sectional views showing steps in the manufacture of a memory cell according to the second embodiment;

FIGS. 20A and 20B are sectional views showing the structure of a memory cell according to the third embodiment;

FIGS. 21A, 21B, 22A, 22B, 23A, 23B, 24A, 24B, 25A, 25B, 26A, 26B, 27A, 27B, 28A, 28B, 29A, 29B, 30A, and 30B are sectional views showing steps in the manufacture of the memory cell according to the third embodiment;

FIGS. 31A, 31B, 32A, 32B, 33A, 33B, 34A, 34B, 35A, 35B, 36A, 36B, 37A, 37B, 38A, 38B, 39A, 39B, 40A, and 40B are sectional views showing steps in the manufacture of a memory cell according to the fourth embodiment;

FIGS. 41A, 41B, 42A, 42B, 43A, 43B, 44A, 44B, 45A, 45B, 46A, 46B, 47A, 47B, 48A, 48B, 49A, 49B, 50A, and 50B are sectional views showing steps in the manufacture of a memory cell according to the fifth embodiment;

FIGS. 51A, 51B, 52A, 52B, 53A, 53B, 54A, 54B, 55A, 55B, 56A, 56B, 57A, and 57B are sectional views showing steps in the manufacture of a memory cell according to the sixth embodiment; and

FIGS. 58, 59, 60, and 61 are sectional views showing a method of manufacturing an interconnection structure according to an application example.

### DETAILED DESCRIPTION

In general, according to one embodiment, a method of manufacturing a semiconductor device is provided. In the method of manufacturing a semiconductor device, a first layer containing Si is formed on a semiconductor substrate. An impurity region and a non-impurity region are formed in the first layer by selectively diffusing an impurity into the first layer. A second layer containing a metal material is formed on the first layer. The metal material is diffused into the non-impurity region by annealing the second layer.

The embodiments will now be described with reference to the accompanying drawing. The same reference numerals denote the same parts throughout the drawings. A repetitive explanation will be made as needed.

### First Embodiment

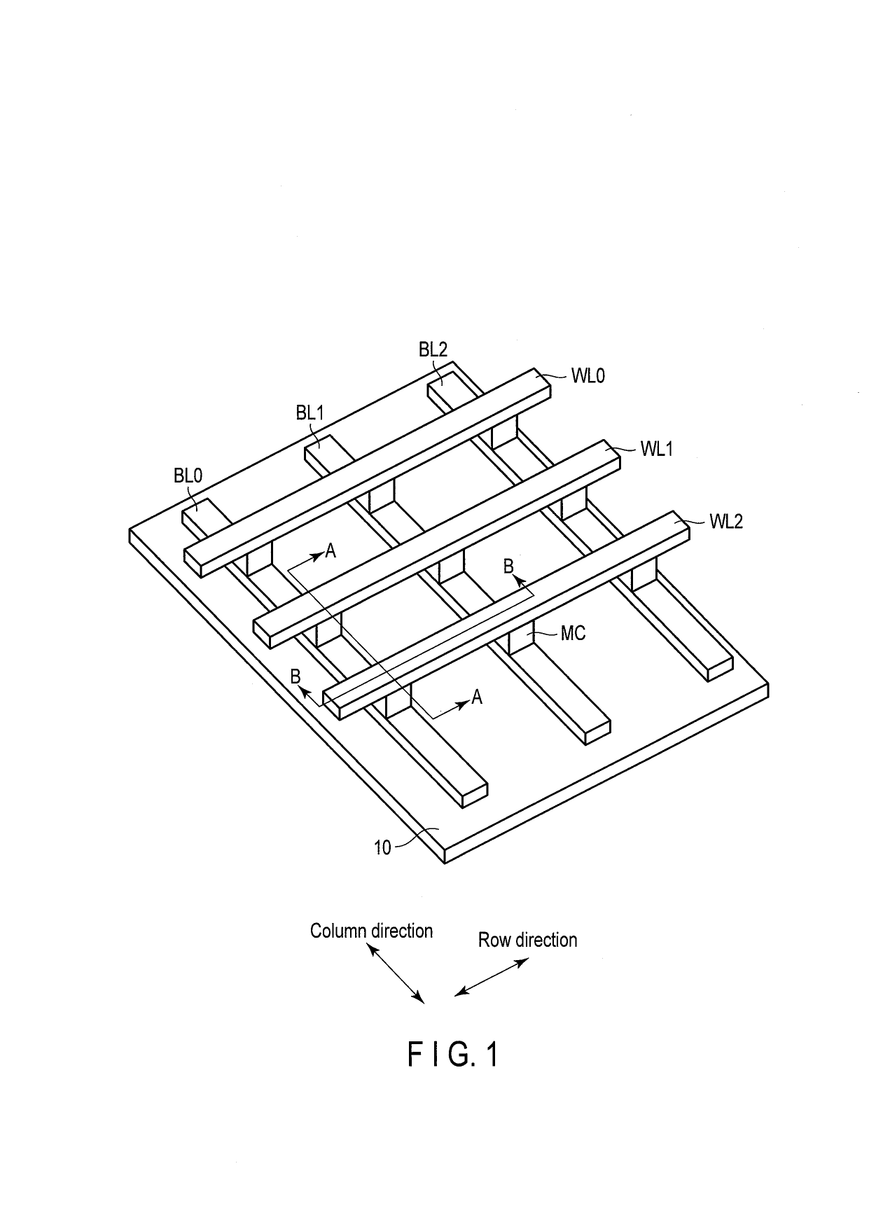

A semiconductor device (ReRAM) according to the first embodiment will be described with reference to FIGS. 1, 2A, 2B, 3A, 3B, 4A, 4B, 5A, 5B, 6A, 6B, 7A, 7B, 8A, 8B, 9A, 9B, 10A, 10B, 11A, 11B, 12A, 12B, 13, 14, 15, and 16. In the first embodiment, a metal layer 23 containing Ag is formed on an a-Si layer 15 including an impurity region 21 and a non-impurity region 22, and annealing is performed to impregnate the non-impurity region 22 with Ag, thereby forming an upper electrode 13. This makes it possible to form the

Ag electrode, which is hard to process, into a desired shape. The first embodiment will be described below in detail.

### [Structure]

The structure of the semiconductor device according to the first embodiment will be described below with reference to FIGS. 1, 2A, 2B, 3A, and 3B.

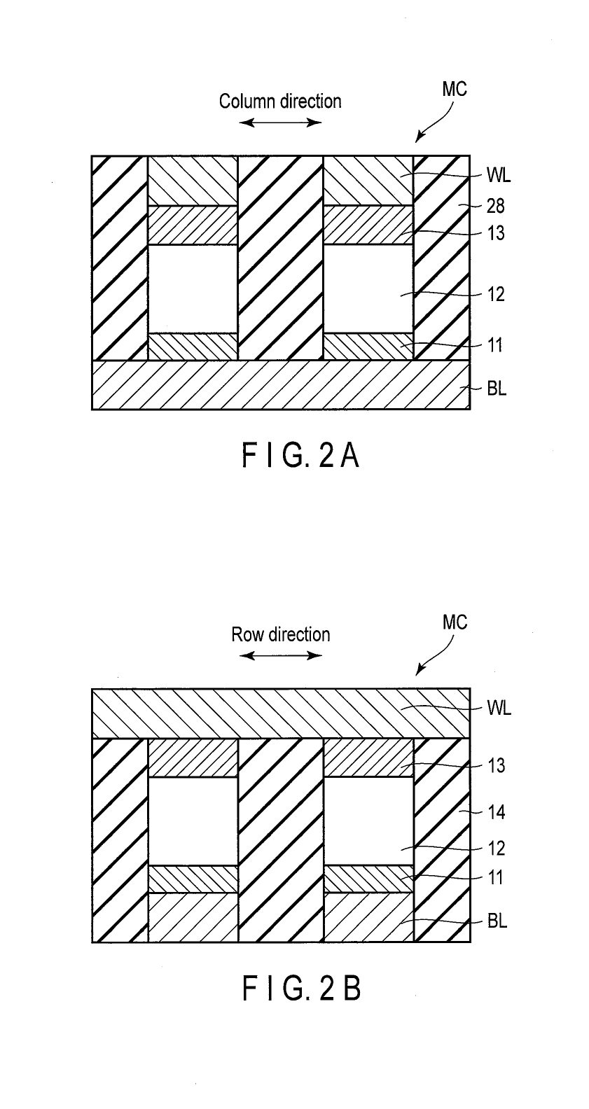

FIG. 1 is a perspective views showing an example of the arrangement of a memory cell array according to the first embodiment. FIGS. 2A and 2B are sectional views showing the structure of a memory cell MC according to the first embodiment. More specifically,

FIG. 2A is a sectional view taken along a line A-A in FIG. 1. FIG. 2B is a sectional view taken along a line B-B in FIG. 1.

As shown in FIG. 1, the memory cell array comprises a plurality of bit lines BL0 to BL2 formed on an insulating film (not shown) on a semiconductor substrate 10, a plurality of word lines WL0 to WL2, and a plurality of memory cells MC. Note that in the following explanation, the bit lines BL0 to BL2 will be simply referred to as bit lines BL, and the word lines WL0 to WL2 will be simply referred to as word lines WL if distinction is not particularly needed.

The bit lines BL0 to BL2 run in the column direction parallel to each other. The word lines WL0 to WL2 are formed above the bit lines BL0 to BL2 so as to run in the row direction parallel to each other.

The bit lines BL and the word lines WL preferably contain a material that is tolerant of heat and has a low resistance value. Examples of the material of the bit lines BL and the word lines WL are metal materials such as tungsten (W), tungsten silicide (WSi), molybdenum (Mo), molybdenum silicide (MoSi), nickel silicide (NiSi), and cobalt silicide (CoSi), and carbon materials such as carbon nanotubes and graphene.

The memory cells MC are arranged at the intersections between the bit lines BL0 to BL2 and the word lines WL0 to WL2 while being sandwiched between them. That is, the memory cell array has a so-called cross point memory structure.

As shown in FIGS. 2A and 2B, the memory cell MC comprises a lower electrode 11, a resistance change layer 12, and the upper electrode 13.

The lower electrode 11 is formed on the bit line BL. The lower electrode 11 serves as an underlayer of the resistance change layer 12 to be formed on it. The lower electrode 11 contains, for example, Si heavily doped with an impurity (for example, boron (B)).

Note that the lower electrode 11 may contain n-type Si doped with, for example, As or P. The lower electrode 11 may be a conductive electrode made of a metal such as titanium (Ti), W, or tantalum (Ta), or a carbide or nitride thereof. A conductive material containing a metal material such as platinum (Pt), gold (Au), iridium (Ir), ruthenium (Ru), rhodium (Rh), palladium (Pd), or Mo can also be used for the lower electrode 11.

The lower electrode 11 may be omitted so as to form the resistance change layer 12 directly on the bit line BL.

The resistance change layer 12 is formed on the lower electrode 11. The resistance change layer 12 is a high-resistance layer such as a semiconductor layer and contains, for example, a-Si or polysilicon (poly-Si).

The upper electrode 13 is formed on the resistance change layer 12. The upper electrode 13 contains a low-volatile metal material, for example, at least one of Ag and copper (Cu). The upper electrode 13 may contain silver sulfide (Ag₂S) or copper sulfide (Cu₂S).

Note that the upper electrode 13 preferably contains a material that does not form a silicide with the resistance change layer 12. Hence, the upper electrode 13 preferably contains Ag. The upper electrode 13 is formed by impregnating the upper portion of the a-Si layer 15 with Ag in a manufacturing step to be described later. For this reason, the upper electrode 13 contains not only Ag but also Si. More specifically, the Ag concentration in the upper electrode 13 is about 1.0×10²¹ [atoms/cm].

Impregnation means diffusing Ag in the a-Si layer 15 without bonding with Si. That is, the upper electrode 13 is not in a silicide state in which Ag dissociates the Si-Si bond and diffuses among the Si-Si lattice so that Si and Ag are bonded but in a state in which Ag diffuses into the grain boundary portion without dissociating the Si-Si bond.

The layers (lower electrodes 11, resistance change layers 12, and upper electrodes 13) included in the memory cells MC and the bit lines BL are insulated and isolated by insulating films 14 made of, for example, SiO₂ between the memory cells MC adjacent in the row direction. On the other hand, the layers included in the memory cells MC and the word lines WL are insulated and isolated by insulating films 28 made of, for example, SiO₂ between the memory cells MC adjacent in the column direction.

Each layer included in the memory cell MC has, for example, a circular planar shape but may have an elliptical or rectangular planar shape.

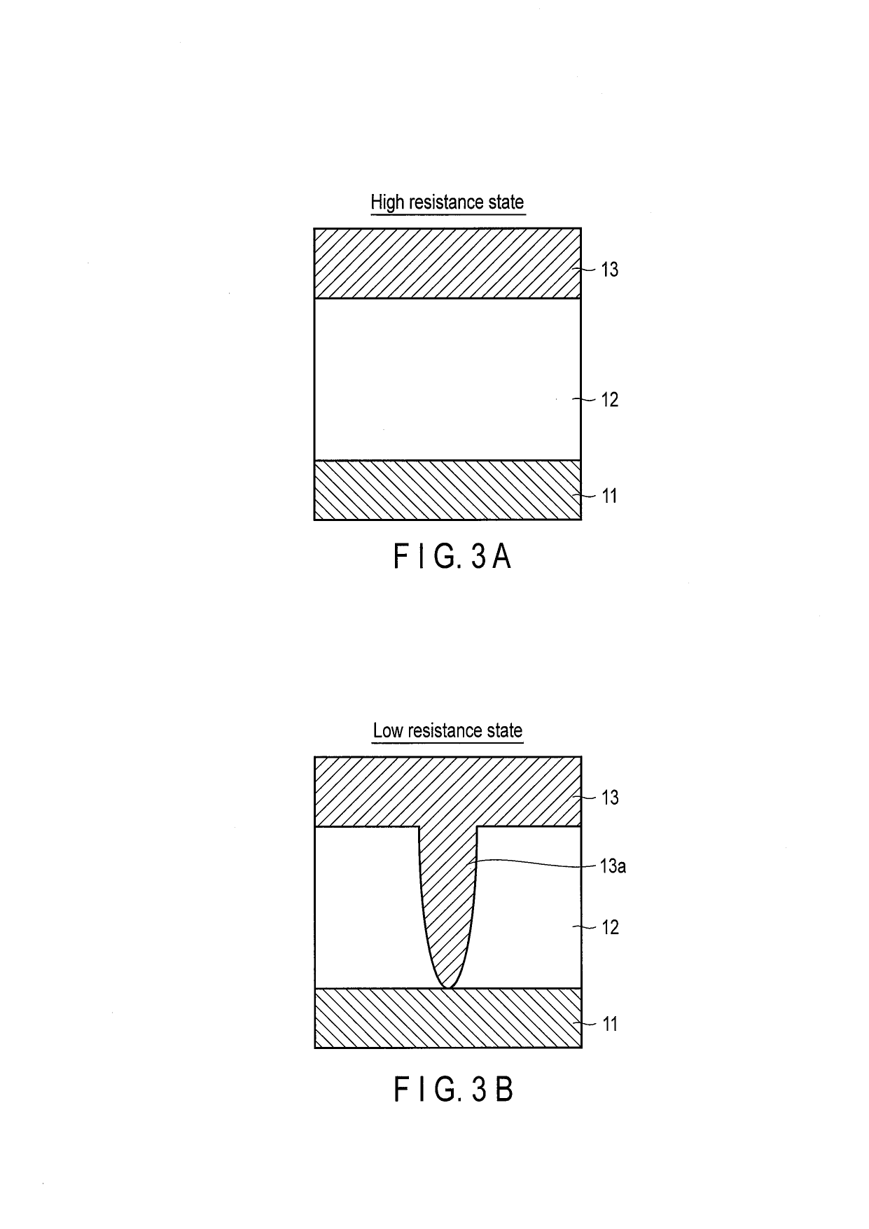

FIGS. 3A and 3B are views showing an example of a resistance change in the resistance change layer 12 according to the first embodiment. FIG. 3A shows a case in which the resistance change layer 12 has a high-resistance state. FIG. 3B shows a case in which the resistance change layer 12 has a low-resistance state.

As shown in FIG. 3A, the initial state of the resistance change layer 12 is the high-resistance state. From this state, the upper electrode 13 is set to a positive voltage, and the lower electrode 11 is set to a fixed voltage (for example, ground voltage) lower than the positive voltage. Then, the metal (for example, Ag) contained in the upper electrode 13 ionizes, diffuses into the main part of the resistance change layer 12, and migrates to the side of the lower electrode 11. The ionized metal that has migrated to the side of the lower electrode 11 receives electrons from the lower electrode 11 so as to precipitate as a metal. That is, a metal filament 13a made of the metal contained in the upper electrode 13 is formed in the resistance change layer 12, as shown in FIG. 3B.

The metal filament 13a gradually extends from the upper electrode 13 to the lower electrode 11. For this reason, the resistance value between the upper electrode 13 and the lower electrode 11 lowers in inverse proportion to the shape such as the length or thickness of the metal filament 13a. Finally, for example, the distal end of the metal filament 13a comes into contact with the lower electrode 11, as shown in FIG. 3B, so that the resistance change layer 12 transits from the high-resistance state to the low-resistance state. This is a set operation.

A reset operation of making the resistance change layer 12 transit from the low-resistance state to the high-resistance state is performed by applying an electric field having a reverse polarity to the main part of the resistance change layer 12. At this time, the metal filament 13a gradually shortens and is disconnected from the lower electrode 11. The resistance change layer 12 thus transits from the low-resistance state to the high-resistance state.

### [Manufacturing Method]

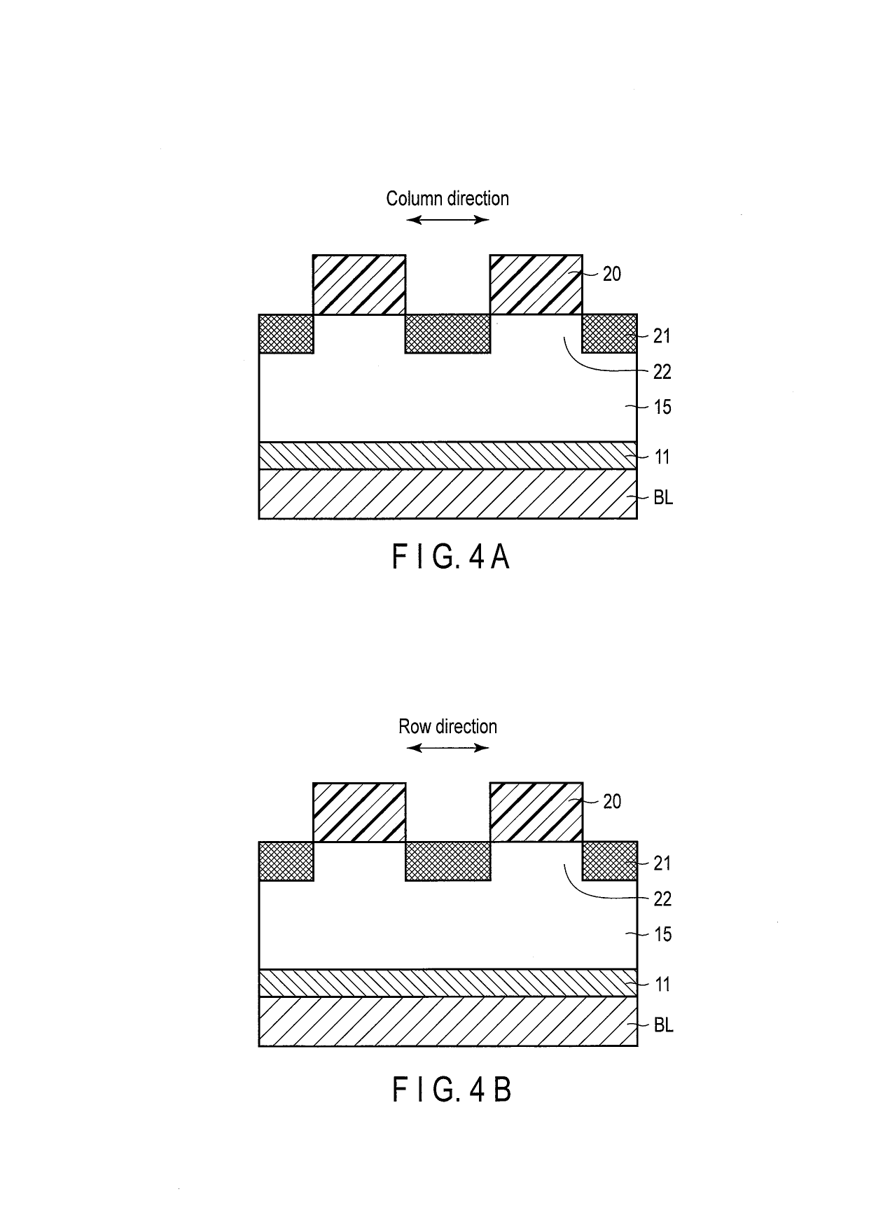

A method of manufacturing the semiconductor device according to the first embodiment will be described below with reference to FIGS. 4A, 4B, 5A, 5B, 6A, 6B, 7A, 7B, 8A, 8B, 9A, 9B, 10A, 10B, 11A, 11B, 12A, and 12B.

FIGS. 4A, 4B, 5A, 5B, 6A, 6B, 7A, 7B, 8A, 8B, 9A, 9B, 10A, 10B, 11A, 11B, 12A, and 12B are sectional views showing steps in the manufacture of a memory cell

MC according to the first embodiment. More specifically, FIGS. 4A, 5A, 6A, 7A, 8A, 9A, 10A, 11A, and 12A are sectional views taken along the line A-A in FIG. 1. FIGS. 4B, 5B, 6B, 7B, 8B, 9B, 10B, 11B, and 12B are sectional views taken along the line B-B in FIG. 1.

First, as shown in FIGS. 4A and 4B, a bit line BL is formed on an insulating film on a semiconductor substrate 10 by, for example, chemical vapor deposition (CVD) or atomic layer deposition (ALD). The bit line

BL contains, for example, a metal material such as W, WSi, Mo, MoSi, NiSi, or CoSi. A lower electrode 11 containing Si doped with, for example, boron is formed on the bit line BL. After that, an a-Si layer 15 is formed on the lower electrode 11 by, for example, CVD or ALD. Note that a poly-Si layer may be formed in place of the a-Si layer 15.

A resist 20 is formed into a desired pattern on the a-Si layer 15. The planar shape of the desired pattern corresponds to the planar shape of an upper electrode 13 to be formed later, and is, for example, circular. That is, the resist 20 is patterned so as to have the same planar shape as that of a memory cell MC.

The upper portion of the a-Si layer 15 is partially selectively doped with an impurity by uniform ion implantation in a direction perpendicular to the surface of the semiconductor substrate 10. Impurity regions 21 having an impurity diffused and non-impurity regions 22 having no impurity diffused are thus formed in the upper portion of the a-Si layer 15. More specifically, the impurity regions 21 are formed in regions that are not covered with the resist 20. The non-impurity regions 22 are formed under the resist 20 (in regions that are covered with the resist 20). Hence, the planar shape of the non-impurity region 22 is the same as that of the resist 20. The impurity regions 21 are regions to be removed later.

The impurity to dope is, for example, oxygen (0). The concentration of the impurity is preferably 1.0×10²¹ [atoms/cm³] or more. The film thickness of the impurity region 21 is preferably 20 nm or more. This makes it possible to prevent the impurity regions 21 from being impregnated with the material (for example, Ag) of a metal layer 23 in a later process. Note that carbon (C) may be used as the impurity in place of oxygen. After that, the impurity regions 21 may be annealed.

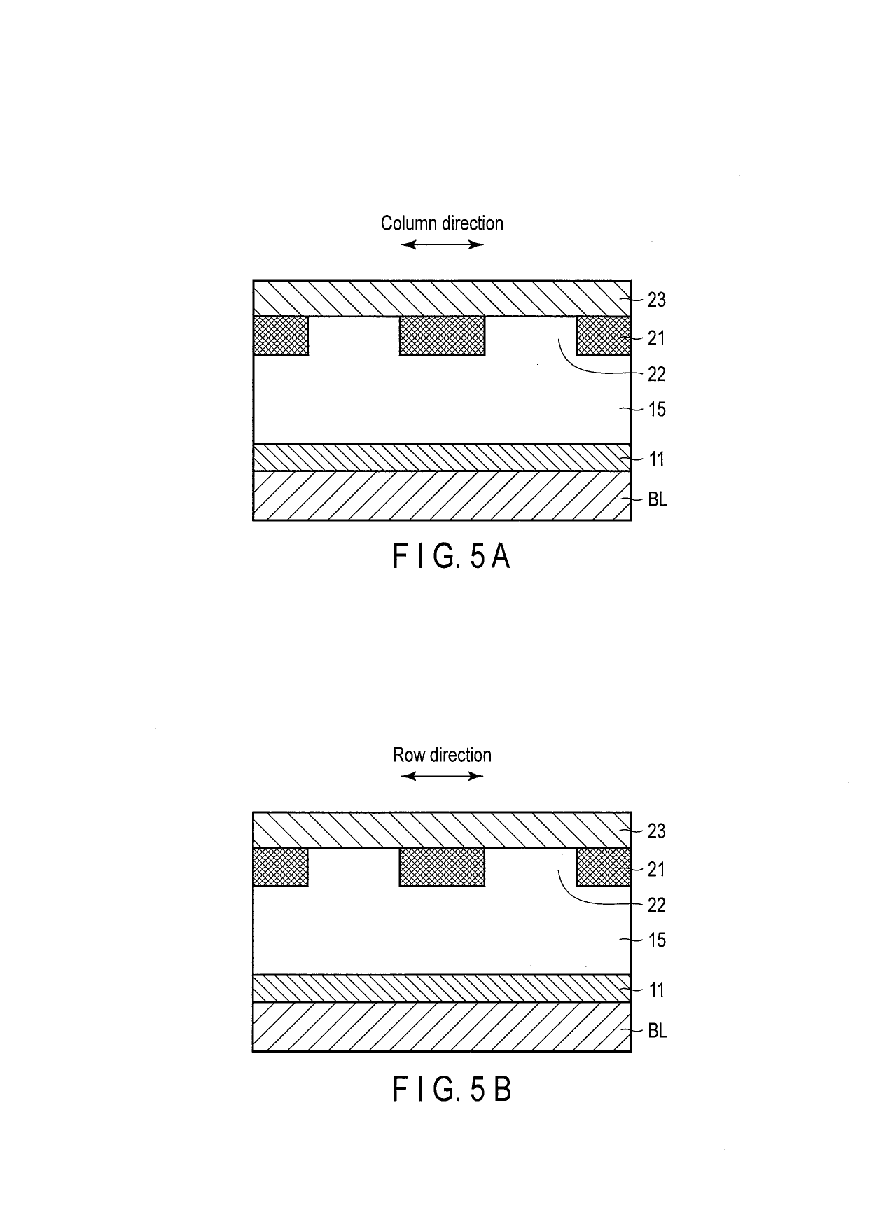

Next, as shown in FIGS. 5A and 5B, after the resist 20 has been removed, the metal layer 23 is formed on the a-Si layer 15 by, for example, physical vapor deposition (PVD) such as sputtering. That is, the metal layer 23 is formed on the impurity regions 21 and the non-impurity regions 22. The metal layer 23 contains a low-volatile metal material, for example, at least one of Ag and Cu. The metal layer 23 may contain Ag₂S or Cu₂S.

Note that the metal layer 23 preferably contains a material that does not form a silicide with the a-Si layer 15. Hence, the metal layer 23 preferably contains Ag. The following description will be made assuming that the metal layer 23 contains Ag.

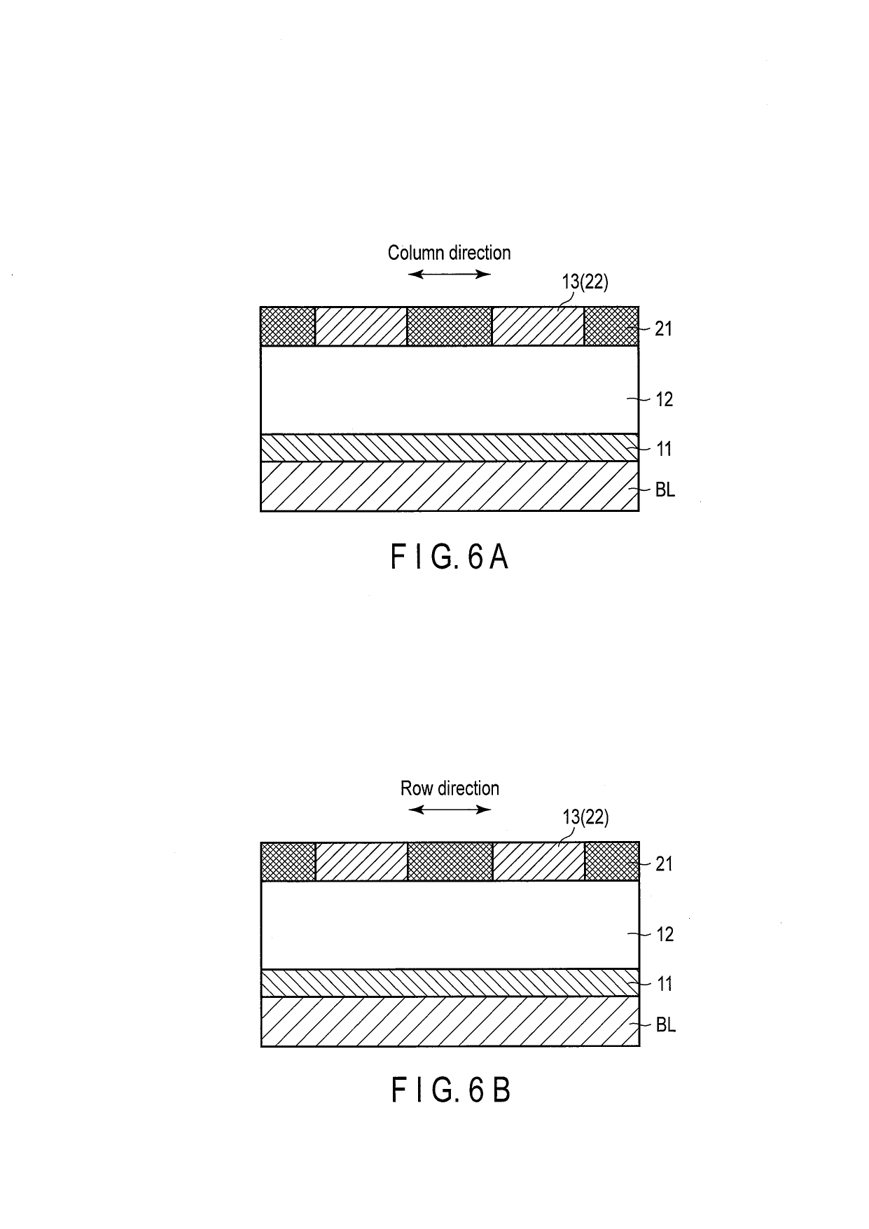

As shown in FIGS. 6A and 6B, the metal layer 23 is annealed. This annealing is performed at a temperature of, for example, 350° C. (inclusive) to 500° C. (inclusive), and preferably, about 400° C. for 1 hr. The non-impurity regions 22 are thus impregnated with Ag contained in the metal layer 23 so that the upper electrodes 13 are formed in the upper portion of the a-Si layer 15. For this reason, the upper electrodes 13 contain Ag and Si.

More specifically, the Ag concentration in the upper electrodes 13 is about 1.0×10²¹ [atoms/cm]. The film thickness (the depth of Ag impregnation) of the upper electrodes 13 is almost the same as that of, for example, the impurity region 21. However, the film thickness is not limited to this and is appropriately adjusted by controlling the temperature and time of annealing. At this time, the impurity regions 21 are not impregnated with Ag. In addition, a resistance change layer 12 is formed in the lower portion of the a-Si layer 15 that is not impregnated with Ag.

Ag impregnation (diffusion) in the impurity regions 21 and the non-impurity regions 22 in the annealing process will be described later in detail.

The metal layer 23 remaining on the upper electrodes 13 and the impurity regions 21 is removed by wet etching using hydrofluoric acid such as DHF (Dilute Hydrofluoric Acid). At this time, the Ag contained in the upper electrodes 13 is not removed because it is impregnated in the a-Si layer 15. As a result, only the metal layer 23 can selectively be removed.

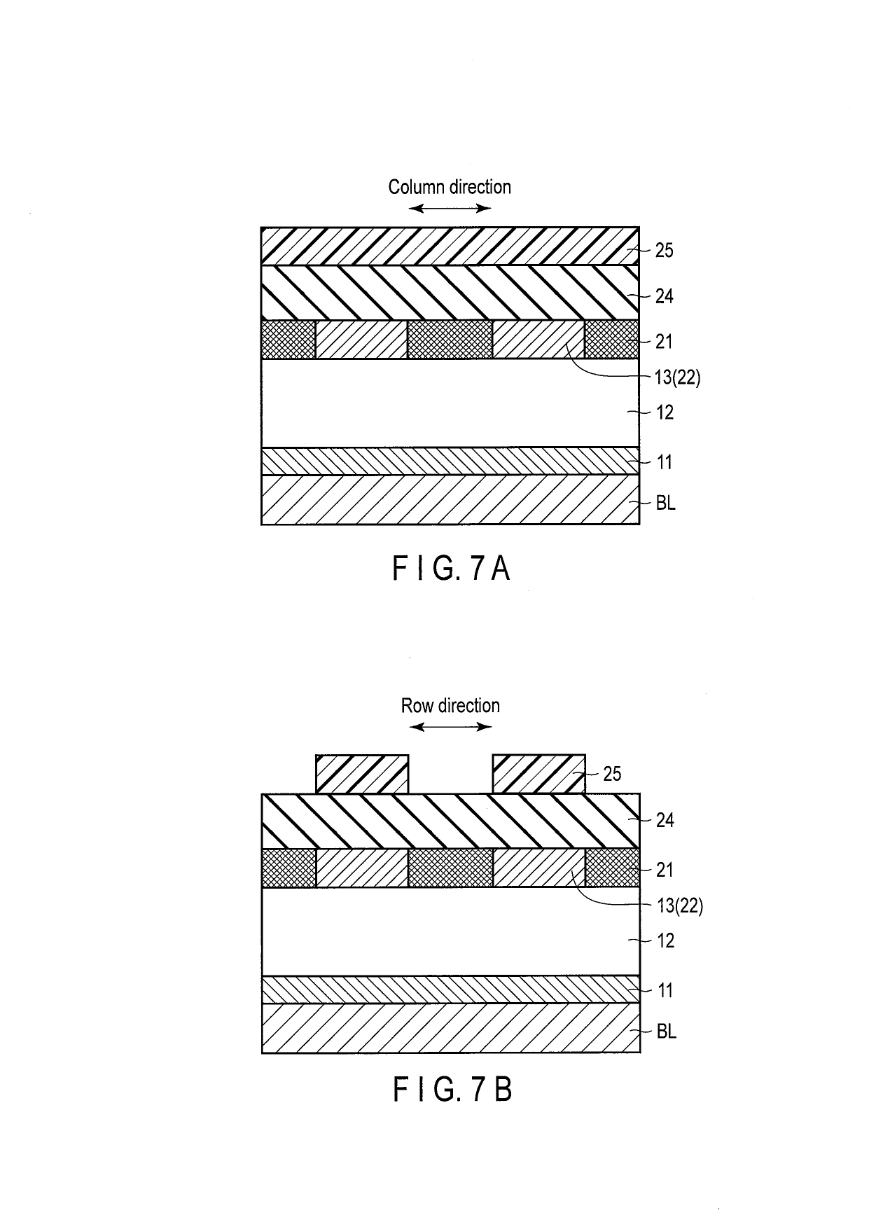

As shown in FIGS. 7A and 7B, a hard mask 24 containing, for example, SiN is formed on the upper electrodes 13 and the impurity regions 21. A resist 25 is formed into a desired pattern on the hard mask 24. The resist 25 runs in the column direction. In the row direction, the resist 25 has almost the same size as that of each upper electrode 13 and is formed at the same position as the upper electrode 13. In other words, the resist 25 overlaps each upper electrode 13 in the row direction.

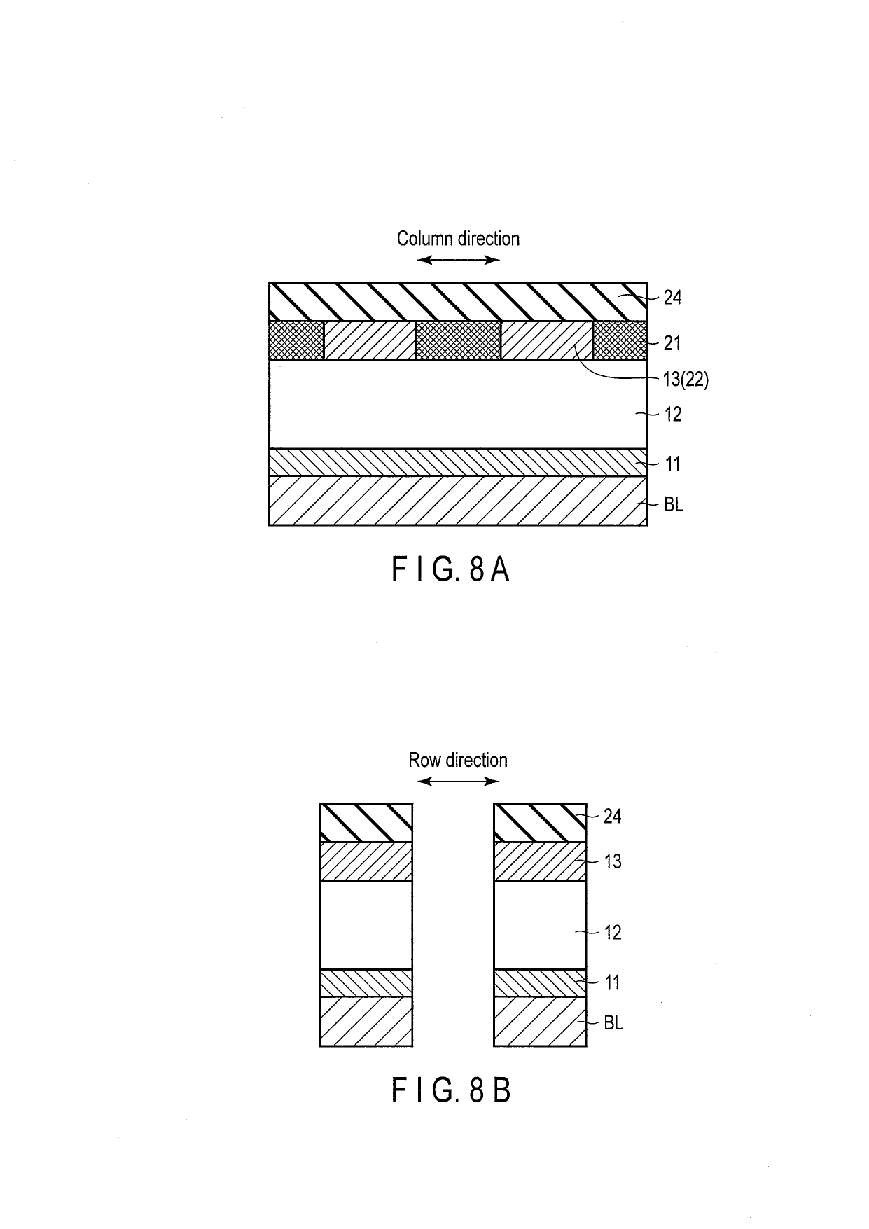

As shown in FIGS. 8A and 8B, the hard mask 24 is processed by, for example, RIE using the resist 25 as a mask. After that, the resist 25 is removed by, for example, wet etching.

Next, the impurity regions 21, the resistance change layer 12, the lower electrode 11, and the bit line BL are processed by, for example, RIE using the hard mask 24 as a mask. The impurity regions 21, the resistance change layer 12, the lower electrode 11, and the bit line BL are thus divided along the column direction. The upper electrodes 13 are not processed at this time because they are divided in advance along the column direction and overlap the hard mask 24 in the row direction. In other words, the upper electrodes 13 need not be processed by RIE.

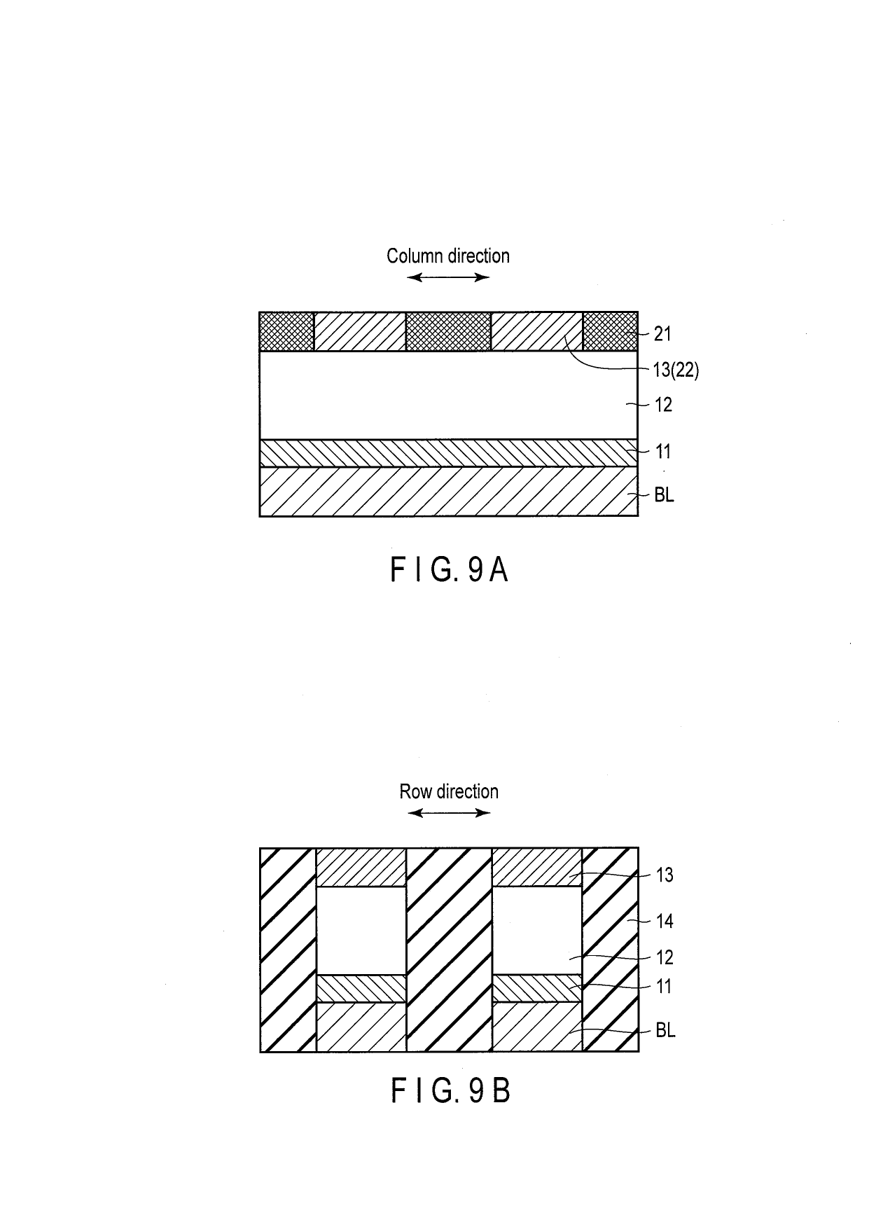

As shown in FIGS. 9A and 9B, the hard mask 24 is removed. After that, insulating films 14 containing, for example, SiO₂ are formed between the upper electrodes 13, the impurity regions 21, the resistance change layers 12, the lower electrodes 11, and the bit lines BL, which are divided along the column direction.

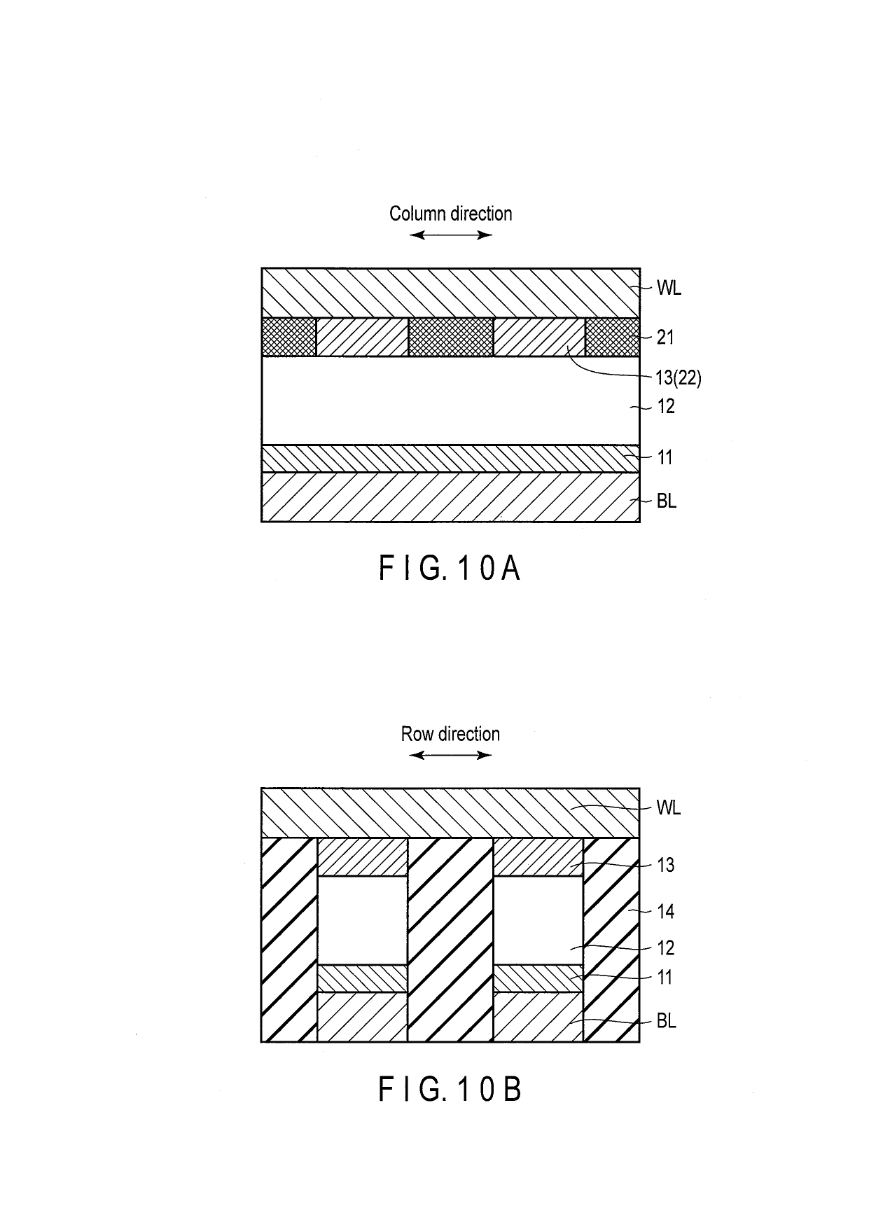

As shown in FIGS. 10A and 10B, a word line WL is formed on the upper electrodes 13, the impurity regions 21, and the insulating films 14 by CVD or ALD. The word line WL contains a metal material such as W, WSi, Mo, MoSi, NiSi, or CoSi.

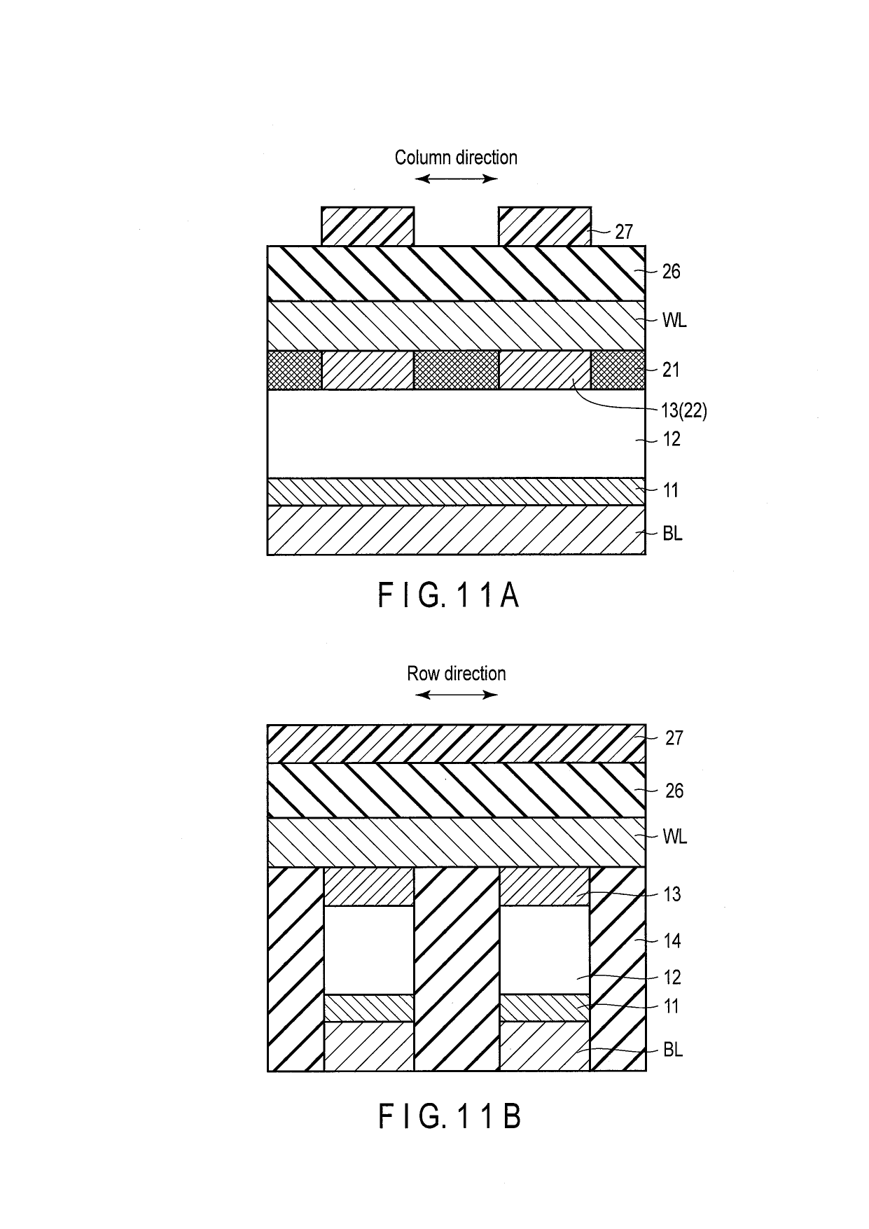

As shown in FIGS. 11A and 11B, a hard mask 26 containing, for example, SiN is formed on the word line WL. A resist 27 is formed into a desired pattern on the hard mask 26. The resist 27 runs in the row direction. In the column direction, the resist 27 has almost the same size as that of each upper electrode 13 and is formed at the same position as the upper electrode 13. In other words, the resist 27 overlaps each upper electrode 13 in the column direction.

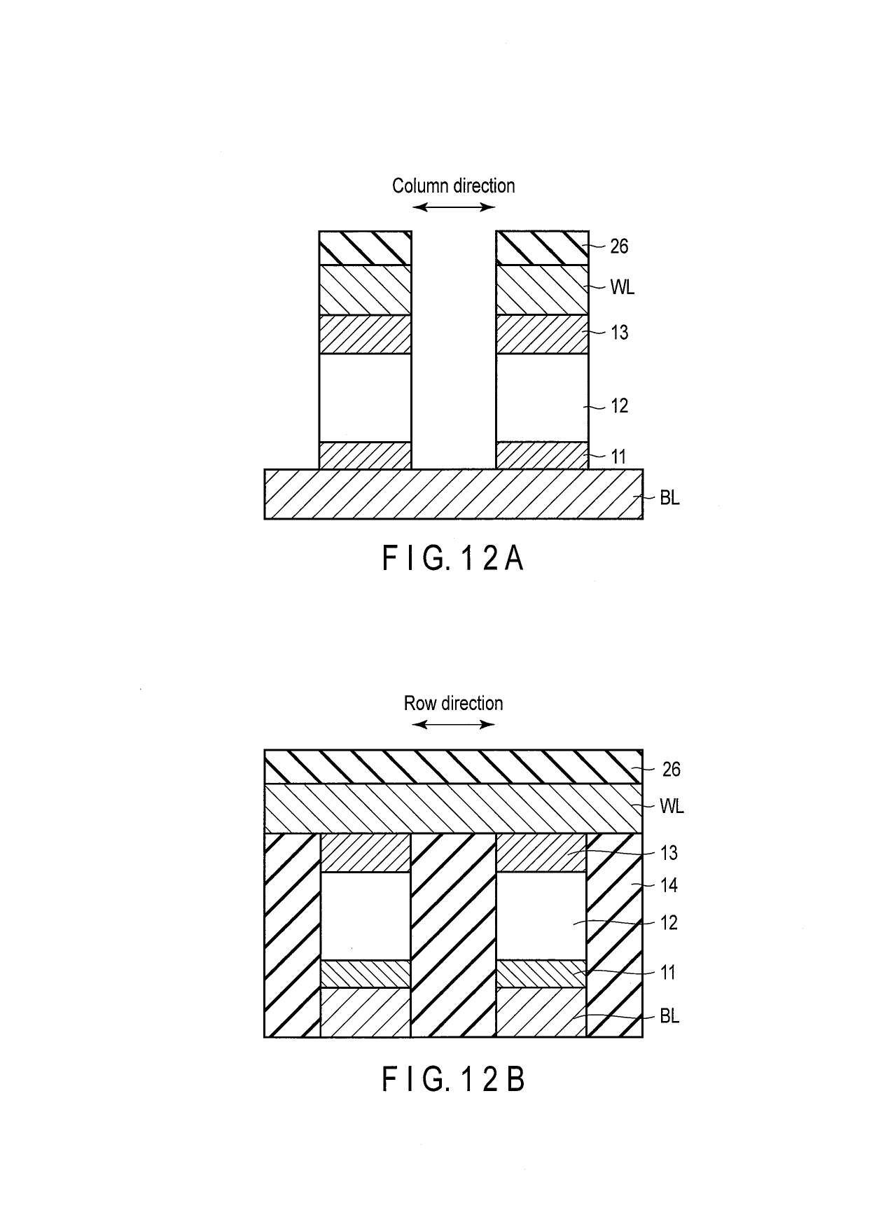

As shown in FIGS. 12A and 12B, the hard mask 26 is processed by, for example, RIE using the resist 27 as a mask. After that, the resist 27 is removed by, for example, wet etching.

Next, the word line WL, the impurity regions 21, the resistance change layer 12, and the lower electrode 11 are processed by, for example, RIE using the hard mask 26 as a mask. The impurity regions 21 are thus removed, and the word line WL, the resistance change layer 12, and the lower electrode 11 are divided along the row direction. Hence, the resistance change layer 12 and the lower electrode 11 included in the memory cells MC are divided along the column direction and the row direction. The upper electrodes 13 are not processed at this time because they are divided in advance along the row direction and overlap the hard mask 26 in the column direction. In other words, the upper electrodes 13 need not be processed by RIE.

Next, as shown in FIGS. 2A and 2B, the hard mask 26 is removed. After that, insulating films 28 containing, for example, SiO₂ are formed between the word lines WL, the upper electrodes 13, the resistance change layers 12, and the lower electrodes 11, which are divided along the row direction.

In the above-described way, the memory cell MC and the cross point memory structure according to the first embodiment are formed.

### [Ag Diffusion by Annealing]

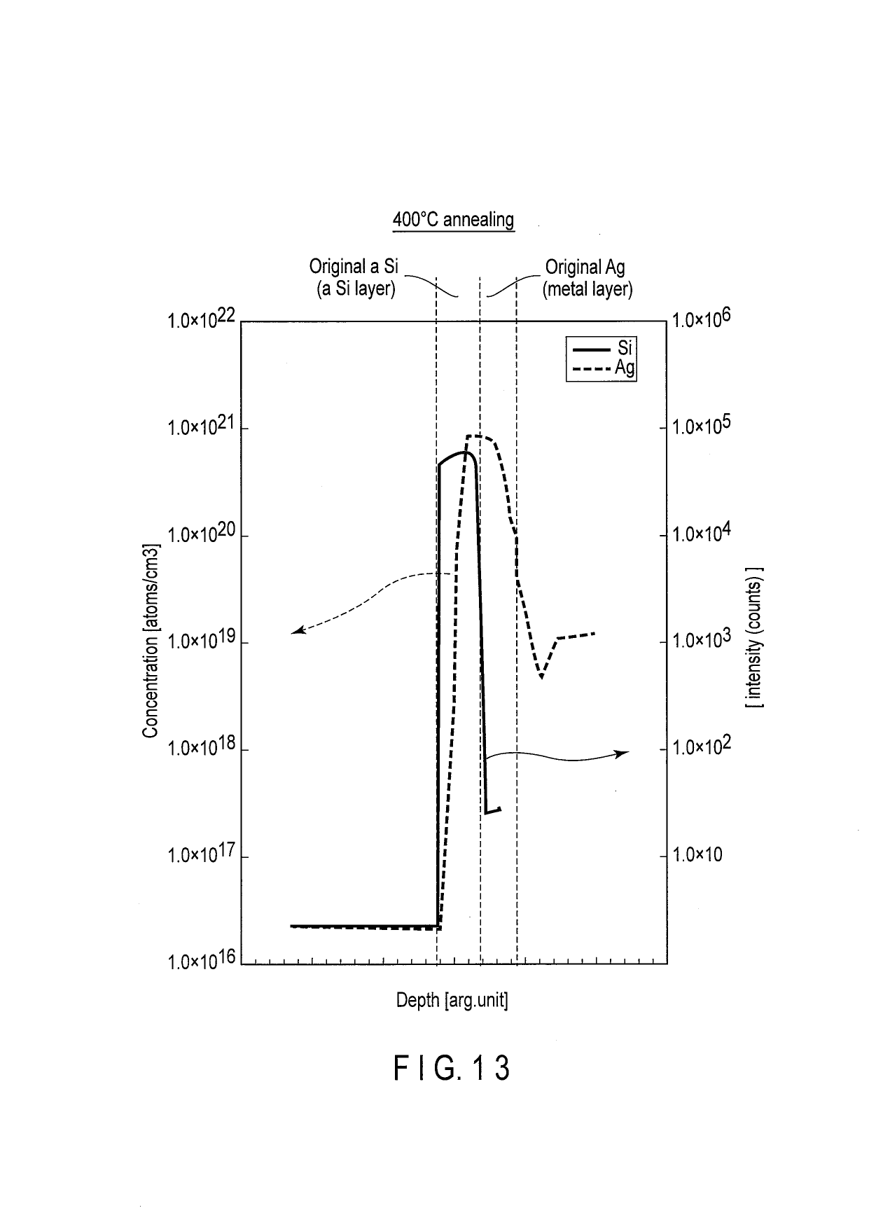

Ag diffusion in the annealing process will be described below with reference to FIGS. 13, 14, 15, and 16.

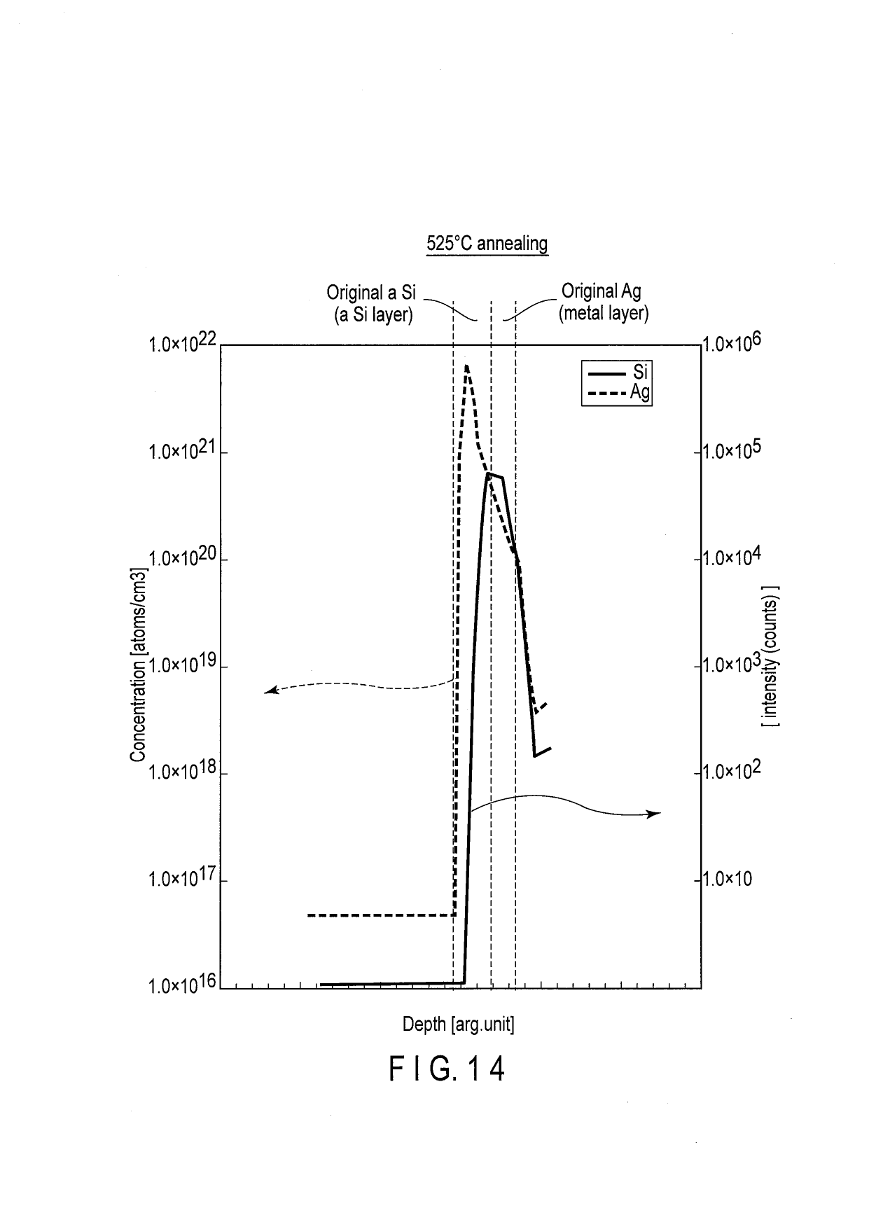

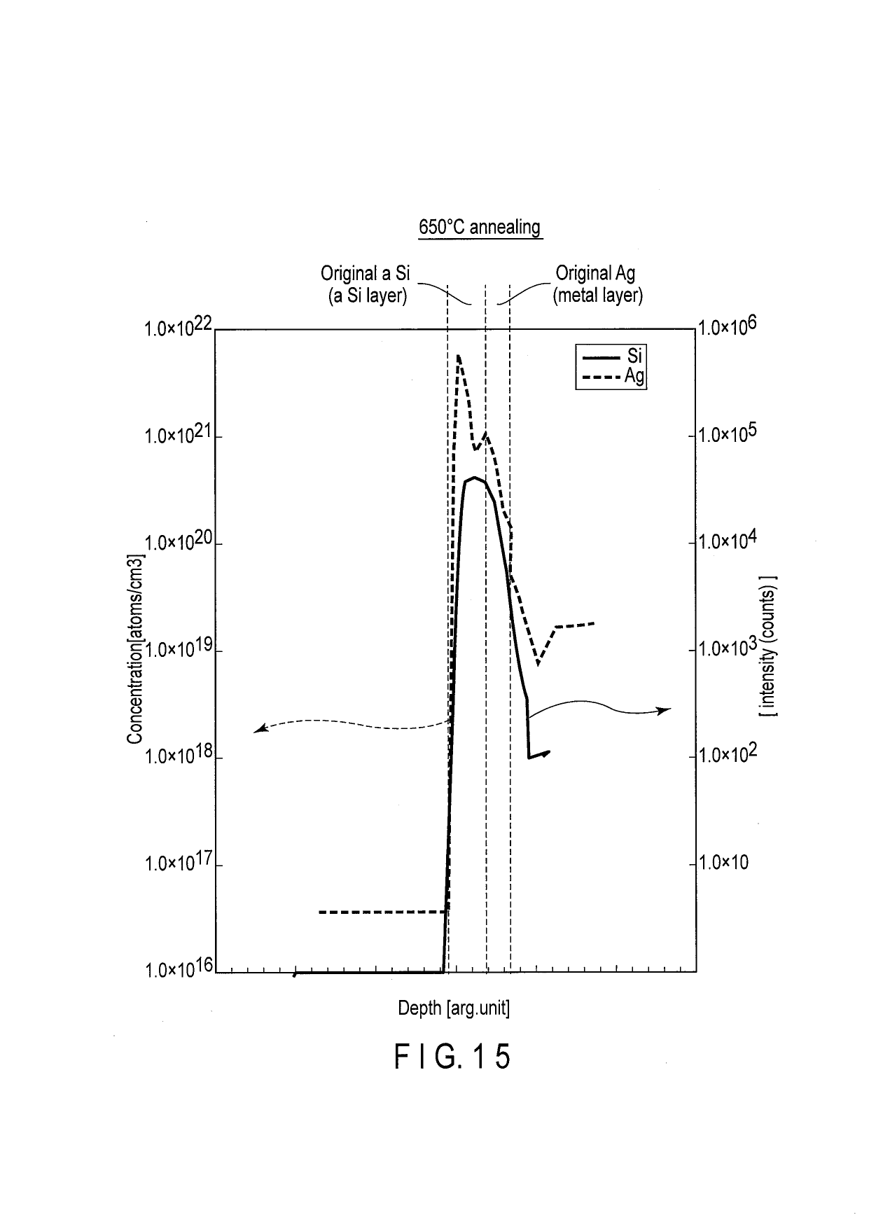

FIG. 13 is a graph showing Ag diffusion into the a-Si layer in the annealing process according to the first embodiment. FIG. 14 is a graph showing Ag diffusion into the a-Si layer in the annealing process according to Comparative Example 1. FIG. 15 is a graph showing Ag diffusion into the a-Si layer in the annealing process according to Comparative Example 2. More specifically, FIG. 13 is a graph showing Ag and Si concentrations after the annealing process at 400° C. FIG. 14 is a graph showing Ag and Si concentrations after the annealing process at 525° C. FIG. 15 is a graph showing Ag and Si concentrations after the annealing process at 650° C.

As described above, in the first embodiment, after the metal layer 23 containing Ag is formed on the a-Si layer 15, annealing is performed to impregnate the upper portion of the a-Si layer 15 with Ag. At this time, the degree of Ag impregnation in the a-Si layer 15 is controlled by the annealing temperature.

When the annealing process is performed at 400° C. in the first embodiment, the upper portion of the a-Si layer 15 is impregnated with Ag, as shown in FIG. 13. The concentration of Ag impregnated in a-Si is about 1.0×10²¹ [atoms/cm]. That is, the upper portion of the a-Si layer 15 (upper electrodes 13) contains Si and Ag in a mixed state.

At this time, Si and Ag do not bond, and no silicide state is formed.

To the contrary, when the annealing process is performed at 525° C. in Comparative Example 1, the entire a-Si layer 15 is impregnated with Ag, as shown in FIG. 14. The concentration of Ag impregnated in the a-Si layer 15 is higher that in the first embodiment in which the annealing process is performed at 400° C., and more specifically, about 1.0×10²² [atoms/cm]. In other words, the degree of Ag diffusion is higher than in the first embodiment. At this time, Si of the a-Si layer 15 migrates to the side of the metal layer 23.

That is, Si of the a-Si layer 15 and Ag of the metal layer 23 change places. In this case, since Si and Ag do not mix, the upper electrodes 13 cannot be formed into a desired shape in the process of removing extra Ag (for example, FIGS. 6A and 6B).

In addition, when the annealing process is performed at 650° C. in Comparative Example 2, the entire a-Si layer 15 is impregnated with Ag, as in Comparative Example 1, and the Ag concentration rises near the interface between the original Ag and the a-Si layer 15, as shown in FIG. 15. This is supposedly because the degree of Ag diffusion is higher than in

Comparative Example 1. That is, Ag is temporarily diffused into the entire a-Si layer 15 and then diffused again near the interface between the original Ag and the a-Si layer 15. In this case, since Si and Ag do not mix, the upper electrodes 13 cannot be formed into a desired shape in the process of removing extra Ag (for example, FIGS. 6A and 6B), as in Comparative Example 1.

As shown in Comparative Examples 1 and 2, when the annealing process is performed at a high temperature, the degree of Ag diffusion becomes high. Hence, in the first embodiment, the annealing process is performed at a temperature of 350° C. (inclusive) to 500° C. (inclusive), and preferably, about 400° C.

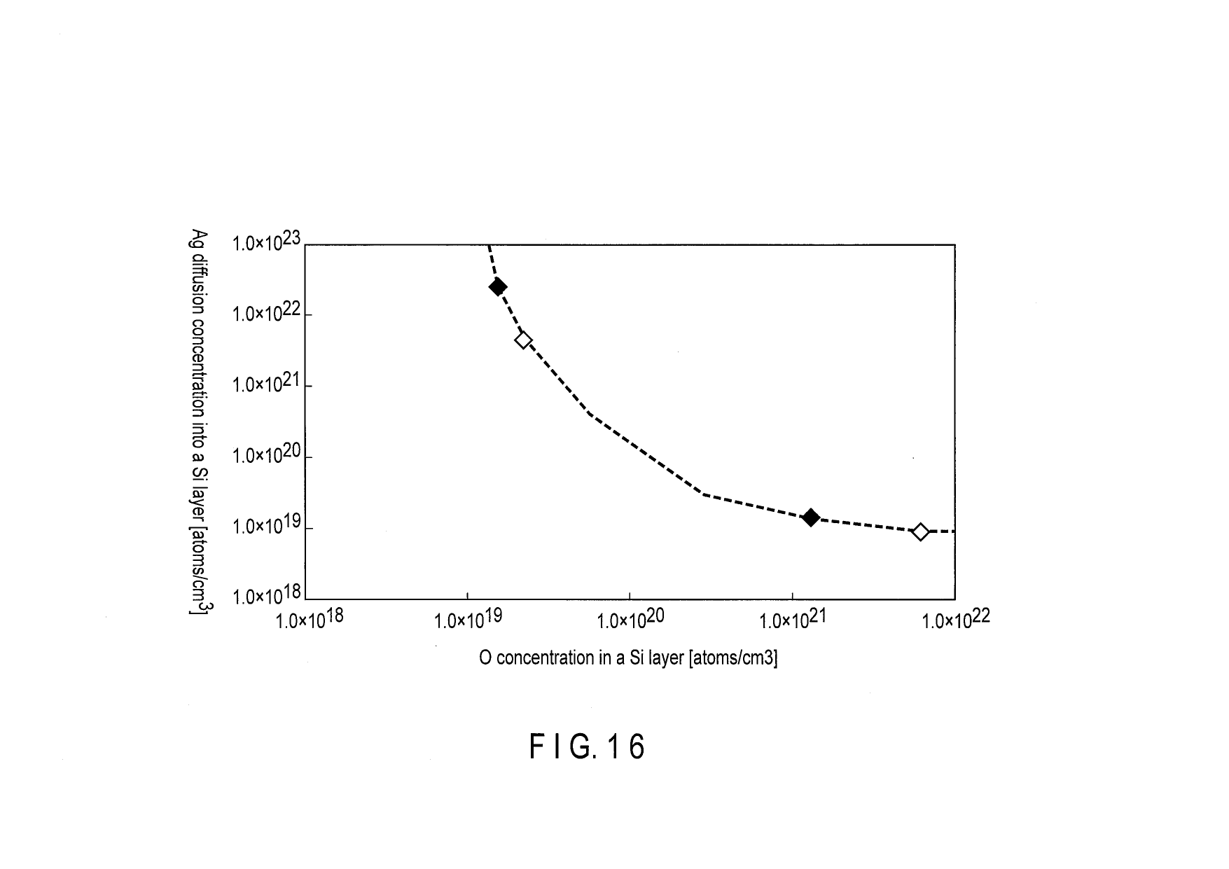

FIG. 16 is a graph showing Ag diffusion with respect to the O concentration in the a-Si layer in the annealing process.

As shown in FIG. 16, the higher the O concentration in the a-Si layer is, the lower the concentration of Ag diffused into the a-Si layer upon annealing is. The reason for this is possibly assumed as follows.

When annealing is performed, Ag receives the thermal energy so as to diffuse into the a-Si layer. When the diffused Ag comes into contact with O in the a-Si layer, charge transfer occurs between them. O obtains (removes) the energy from Ag and suppresses its diffusion. In other words, Ag stabilizes in terms of energy upon contact with O so that the diffusion is suppressed. As described above, increasing the O concentration in the a-Si layer enables to suppress Ag diffusion.

At this time, the O concentration is preferably set to 1.0 ×10²¹ [atoms/cm³] or more. This makes it possible to suppress the concentration of Ag diffused into the a-Si layer to about 1.0 ×10¹⁹ [atoms/cm³], as shown in FIG. 16.

### [Effects]

According to the first embodiment, the metal layer 23 containing Ag is formed on the a-Si layer 15 including the impurity regions 21 doped with O and the non-impurity regions 22. After that, the metal layer 23 is annealed to impregnate the non-impurity regions 22 with Ag, thereby forming the upper electrodes 13.

That is, the non-impurity regions 22 are formed into a desired shape in the a-Si layer 15 to form Ag electrodes having the same shape. This allows to stably form the Ag electrodes, which are hard to process, into a desired shape and eliminate processing failures.

### Second Embodiment

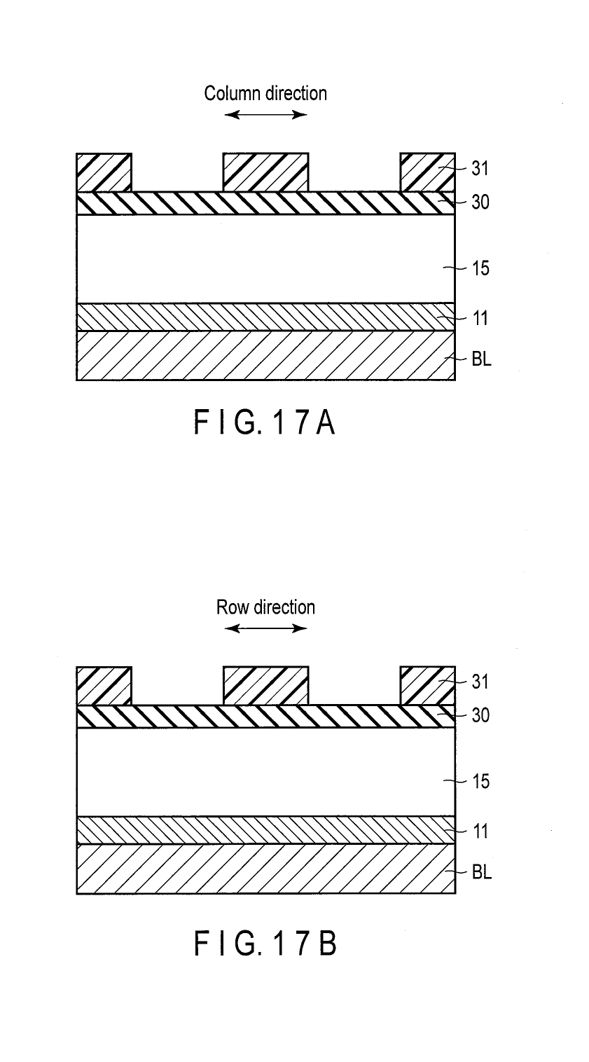

A semiconductor device according to the second embodiment will be described with reference to FIGS. 17A, 17B, 18A, 18B, 19A, and 19B. The second embodiment is a modification of the first embodiment, in which in place of the impurity regions 21 of the first embodiment, a silicon oxide film 30 patterned into a desired shape is formed on an a-Si layer 15 not to allow Ag diffusion. The second embodiment will be described below in detail. Note that in the second embodiment, a description of the same points as in the first embodiment will be omitted, and different points will mainly be explained.

### [Manufacturing Method]

A method of manufacturing the semiconductor device according to the second embodiment will be described below with reference to FIGS. 17A, 17B, 18A, 18B, 19A, and 19B.

FIGS. 17A, 17B, 18A, 18B, 19A, and 19B are sectional views showing steps in the manufacture of a memory cell MC according to the second embodiment.

More specifically, FIGS. 17A, 18A, and 19A are sectional views taken along a line A-A in FIG. 1. FIGS. 17B, 18B, and 19B are sectional views taken along a line B-B in FIG. 1.

First, as shown in FIGS. 17A and 17B, a bit line

BL is formed on an insulating film on a semiconductor substrate 10 by, for example, CVD or ALD. A lower electrode 11 is formed on the bit line BL. After that, an a-Si layer 15 is formed on the lower electrode 11 by, for example, CVD or ALD.

Next, a silicon oxide film 30 is formed on the a-Si layer 15. The film thickness of the silicon oxide film 30 is, for example, about 10 nm. A resist 31 is formed into a desired pattern on the silicon oxide film 30. The desired pattern is formed so as to remove the planar shape portion of an upper electrode 13 to be formed later. That is, the resist 31 is patterned so as to have, in each portion to be removed, the same planar shape as that of a memory cell MC.

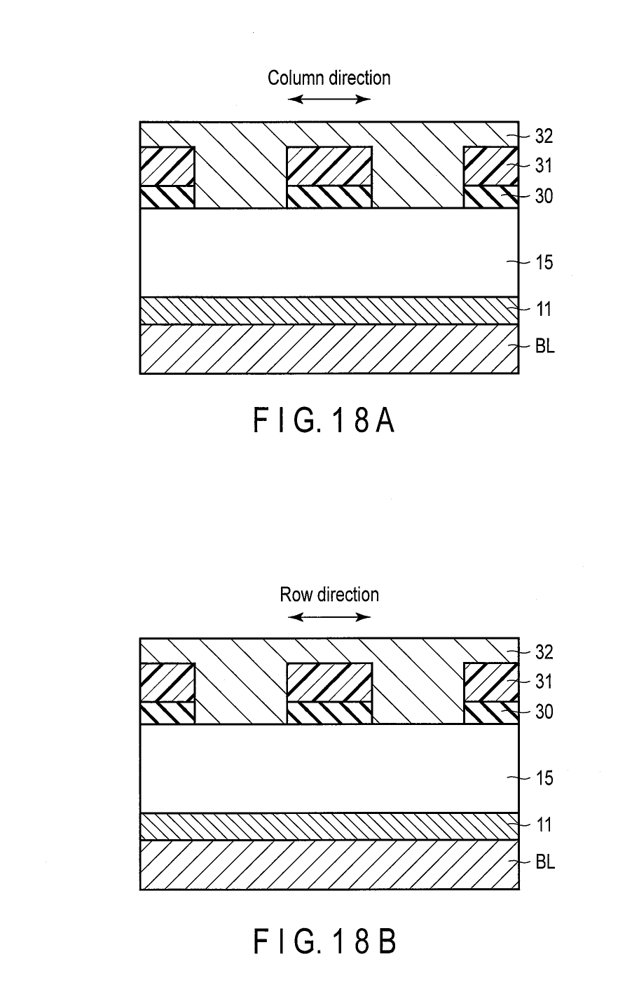

As shown in FIGS. 18A and 18B, the silicon oxide film 30 is processed by, for example, RIE using the resist 31 as a mask. The a-Si layer 15 is thus partially exposed. In other words, the silicon oxide films 30 are selectively formed on the a-Si layer 15. After that, the resist 31 may be removed.

Next, a metal layer 32 is formed on the entire surface by, for example, PVD such as sputtering. More specifically, the metal layer 32 is formed on the resist 31 and the exposed a-Si layer 15. The metal layer 32 contains a low-volatile metal material, for example, at least one of Ag and Cu. The metal layer 32 may contain Ag₂S or Cu₂S. The following description will be made assuming that the metal layer 32 contains Ag.

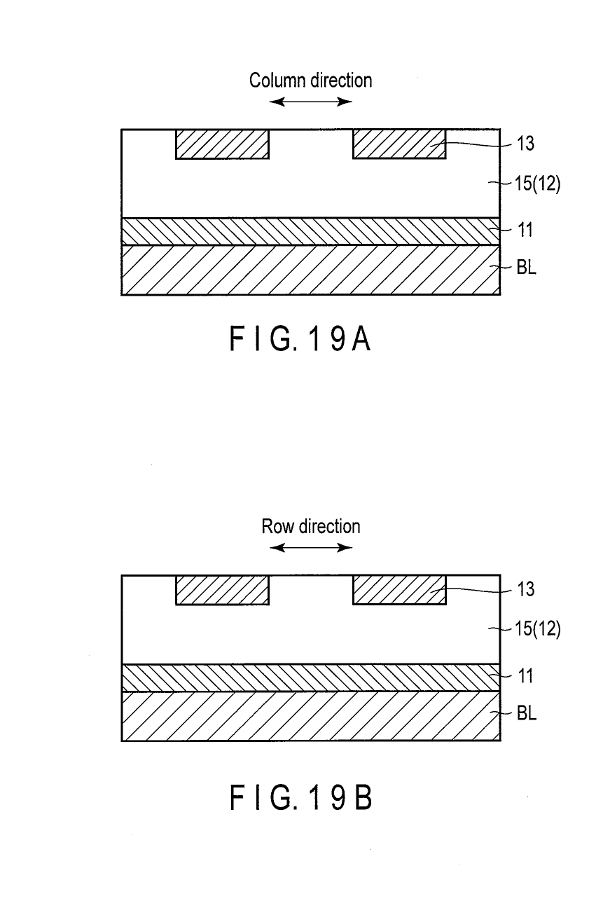

As shown in FIGS. 19A and 19B, the metal layer 32 is annealed. This annealing is performed at a temperature of, for example, 350° C. (inclusive) to 500° C. (inclusive), and preferably, about 400° C. for 1 hr. The a-Si layer 15 is thus partially impregnated with Ag contained in the metal layer 32 so that the upper electrodes 13 are formed in the upper portion of the a-Si layer 15. More specifically, the regions where the a-Si layer 15 and the metal layer 32 are in contact are impregnated with Ag. For this reason, the upper electrodes 13 contain Ag and Si. More specifically, the Ag concentration in the upper electrodes 13 is about 1.0 ×10²¹ [atoms/cm]. The film thickness (the depth of Ag impregnation) of the upper electrodes 13 is appropriately adjusted by controlling the temperature and time of annealing. At this time, the regions covered with the silicon oxide films 30 are not impregnated with Ag. In addition, a resistance change layer 12 is formed in the lower portion of the a-Si layer 15 that is not impregnated with Ag.

The metal layer 32 remaining on the upper electrodes 13 and the resist 31 is removed by wet etching using hydrofluoric acid such as DHF. At this time, the Ag contained in the upper electrodes 13 is not removed because it is impregnated in the a-Si layer 15. As a result, only the metal layer 32 can selectively be removed. In addition, the resist 31 and the silicon oxide films 30 are removed.

After that, the same processes as in FIGS. 7A, 7B, 8A, 8B, 9A, 9B, 10A, 10B, 11A, 11B, 12A, and 12B of the first embodiment are performed, thereby forming the memory cell MC and the cross point memory structure according to the second embodiment.

### [Effects]

According to the second embodiment, the silicon oxide film 30 patterned into a desired shape is formed on the a-Si layer 15 not to diffuse Ag contained in the metal layer 32, thereby forming Ag electrodes having the same shape. This allows to obtain the same effects as in the first embodiment.

### Third Embodiment

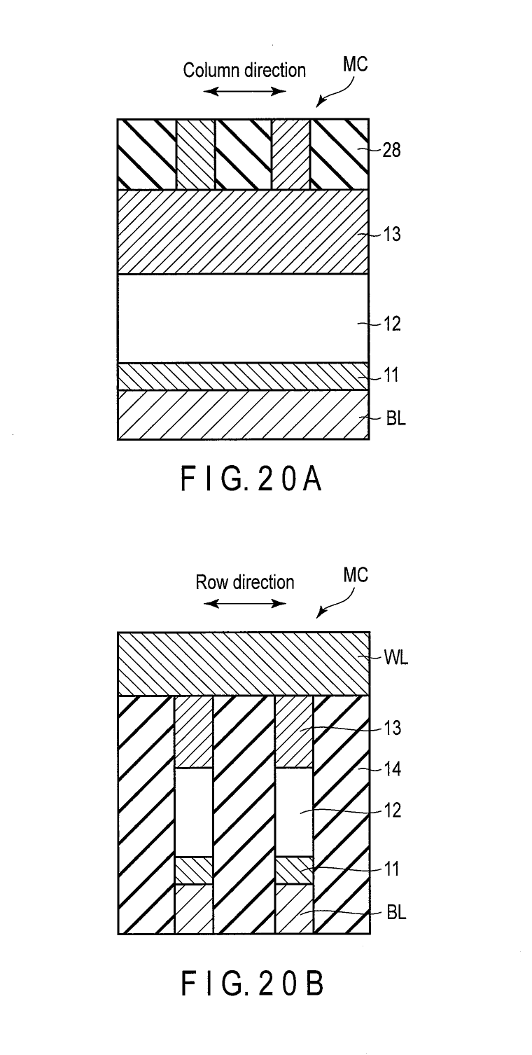

A semiconductor device according to the third embodiment will be described with reference to FIGS. 20A, 20B, 21A, 21B, 22A, 22B, 23A, 23B, 24A, 24B, 25A, 25B, 26A, 26B, 27A, 27B, 28A, 28B, 29A, 29B, 30A, and 30B. In the third embodiment, sidewall members 41 containing a-Si are formed by a so-called sidewall transfer technology and impregnated with Ag to form upper electrodes 13. This makes it possible to form Ag electrodes having a fine pattern unresolvable by lithography. The third embodiment will be described below in detail. Note that in the third embodiment, a description of the same points as in the above-described embodiments will be omitted, and different points will mainly be explained.

### [Structure]

The structure of the semiconductor device according to the third embodiment will be described below with reference to FIGS. 20A and 20B.

FIGS. 20A and 20B are sectional views showing the structure of a memory cell MC according to the third embodiment. More specifically, FIG. 20A is a sectional view taken along a line A-A in FIG. 1. FIG. 20B is a sectional view taken along a line B-B in FIG. 1.

As shown in FIGS. 20A and 20B, the third embodiment is different from the first embodiment in that lower electrodes 11, resistance change layers 12, and the upper electrodes 13 run in the column direction parallel to each other. That is, the lower electrodes 11, the resistance change layers 12, and the upper electrode 13 are sequentially formed on a bit line BL and patterned along the column direction, like the bit line BL.

More specifically, the layers (lower electrodes 11, resistance change layers 12, and upper electrodes 13) included in the memory cells MC and the bit lines BL are insulated and isolated by insulating films 14 made of, for example, SiO₂ between the memory cells MC adjacent in the row direction. On the other hand, word lines WL are insulated and isolated by insulating films 28 made of, for example, SiO₂ between the memory cells MC adjacent in the column direction, and the layers included in the memory cells MC are continuously connected between the memory cells MC adjacent in the column direction.

The lower electrodes 11, the resistance change layers 12, the upper electrodes 13, the bit lines BL, and the word lines WL are processed by a sidewall transfer technology to be described later. For this reason, the lower electrodes 11, the resistance change layers 12, the upper electrodes 13, and the bit lines BL have, in the row direction, sizes unresolvable by lithography. In addition, the word lines WL have, in the column direction, a size unresolvable by lithography.

At this time, the layers included in the memory cells MC are continuously connected between the memory cells MC adjacent in the column direction. The regions functioning as the memory cells MC are arranged at the intersections between the bit lines BL and the word lines WL while being sandwiched between them. In other words, the regions where metal filaments 13a are formed in the resistance change layers 12 are arranged at the intersections between the bit lines BL and the word lines WL while being sandwiched between them. This is because the regions where a voltage difference is generated between the upper electrode 13 and the lower electrode 11 in the set operation and the reset operation are only the regions where the bit lines BL and the word lines WL intersect.

### [Manufacturing Method]

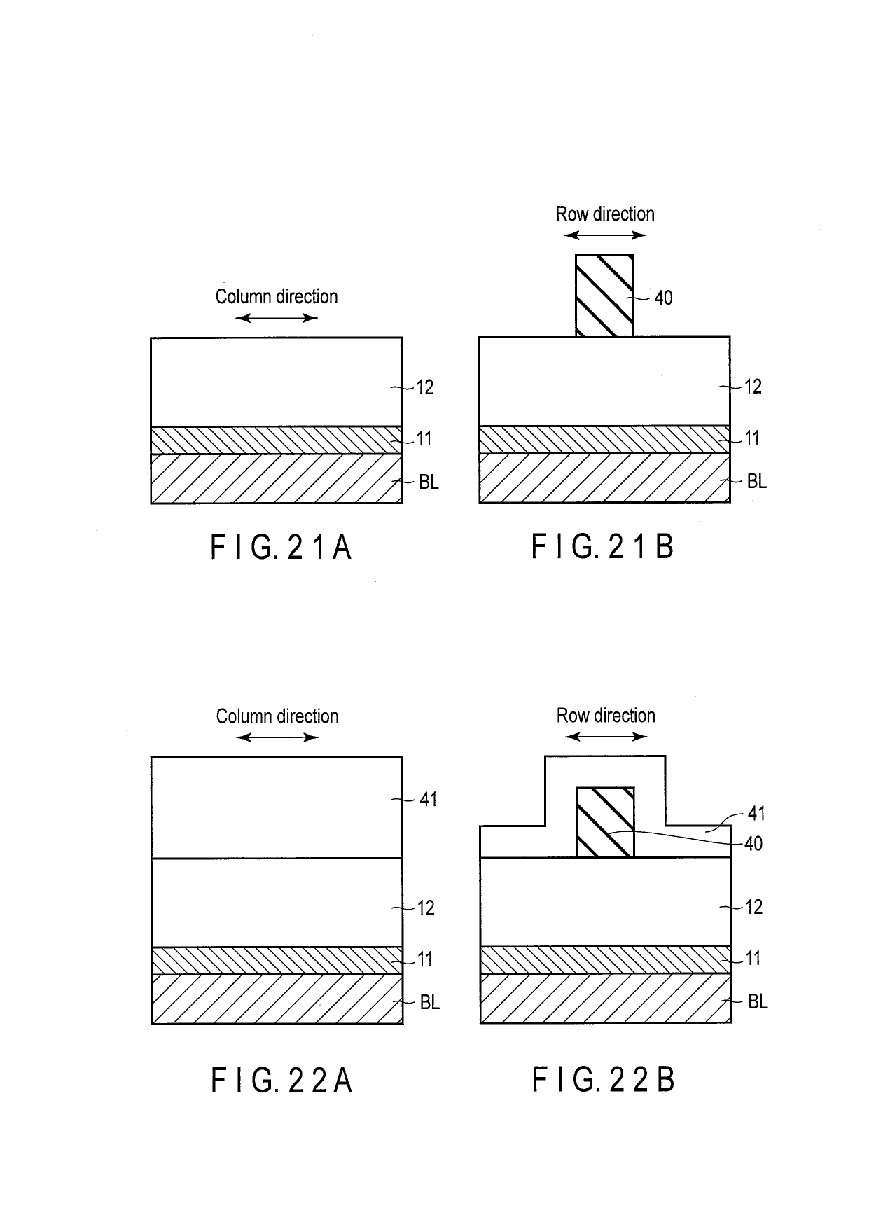

A method of manufacturing the semiconductor device according to the third embodiment will be described below with reference to FIGS. 21A, 21B, 22A, 22B, 23A, 23B, 24A, 24B, 25A, 25B, 26A, 26B, 27A, 27B, 28A, 28B, 29A, 29B, 30A, and 30B.

FIGS. 21A, 21B, 22A, 22B, 23A, 23B, 24A, 24B, 25A, 25B, 26A, 26B, 27A, 27B, 28A, 28B, 29A, 29B, 30A, and 30B are sectional views showing steps in the manufacture of a memory cell MC according to the third embodiment. More specifically, FIGS. 21A, 22A, 23A, 24A, 25A, 26A, 27A, 28A, 29A, and 30A are sectional views taken along the line A-A in FIG. 1. FIGS. 21B, 22B, 23B, 24B, 25B, 26B, 27B, 28B, 29B, and 30B are sectional views taken along the line B-B in FIG. 1.

First, as shown in FIGS. 21A and 21B, a bit line BL is formed on an insulating film on a semiconductor substrate 10 by, for example, CVD or ALD. A lower electrode 11 is formed on the bit line BL. After that, a resistance change layer 12 is formed on the lower electrode 11 by, for example, CVD or ALD. The resistance change layer 12 contains, for example, a-Si or poly-Si.

Next, a core member 40 for sidewall transfer is formed on the resistance change layer 12. More specifically, the core member 40 is formed on the entire surface of the resistance change layer 12 and then patterned by RIE or the like using a resist (not shown) as a mask. The core member 40 is patterned so as to run along the column direction. The core member 40 contains, for example, SiN or SiO₂.

As shown in FIGS. 22A and 22B, a sidewall member 41 is formed on the entire surface by, for example, CVD or ALD. More specifically, the sidewall member 41 is formed on the upper surface of the resistance change layer 12 and the upper surface and side surfaces of the core member 40. The sidewall member 41 contains, for example, a-Si or poky-Si. The film thickness of the sidewall member 41 is, for example, about ½ the row-direction size (width) of the core member 40.

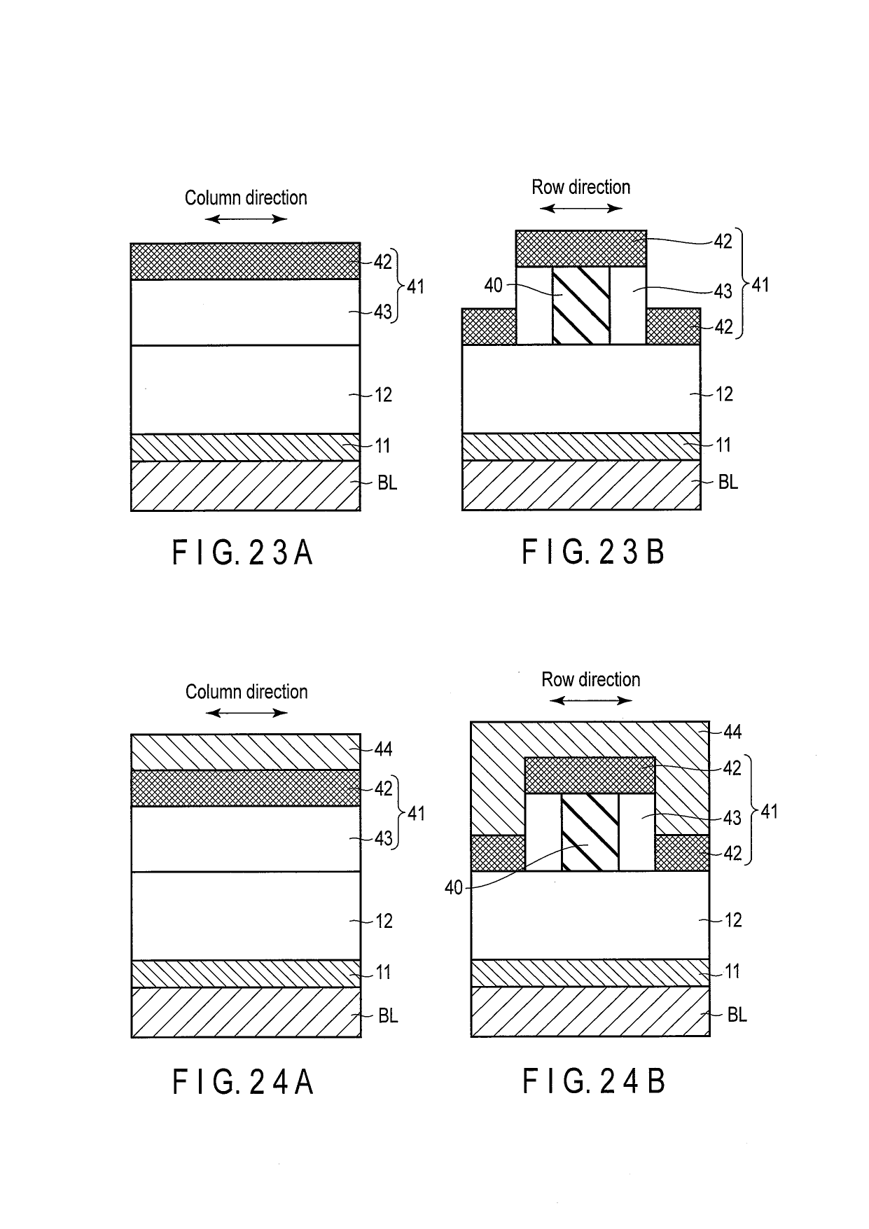

As shown in FIGS. 23A and 23B, the sidewall member 41 is partially doped with an impurity by uniform ion implantation in a direction perpendicular to the surface of the semiconductor substrate 10. More specifically, the sidewall member 41 is doped with the impurity except on the side surfaces of the core member 40. Impurity regions 42 with the impurity diffused are thus formed in the sidewall member 41 formed on the upper surface of the resistance change layer 12 and the upper surface of the core member 40. Non-impurity regions 43 having no impurity diffused are formed in the sidewall member 41 formed on the side surfaces of the core member 40. The non-impurity regions 43 are formed along the core member 40, that is, along the column direction.

The impurity to dope at this time is, for example, oxygen (O). The concentration of the impurity is preferably 1.0×10²¹ [atoms/cm³] or more. This makes it possible to prevent the impurity regions 42 from being impregnated with the material (for example, Ag) of a metal layer 44 in a later process.

Next, as shown in FIGS. 24A and 24B, the metal layer 44 is formed on the sidewall member 41 by, for example, PVD such as sputtering. That is, the metal layer 44 is formed on the impurity regions 42 and the non-impurity regions 43. The metal layer 44 contains a low-volatile metal material, for example, at least one of Ag and Cu. The metal layer 44 may contain Ag₂S or Cu₂S. The following description will be made assuming that the metal layer 44 contains Ag.

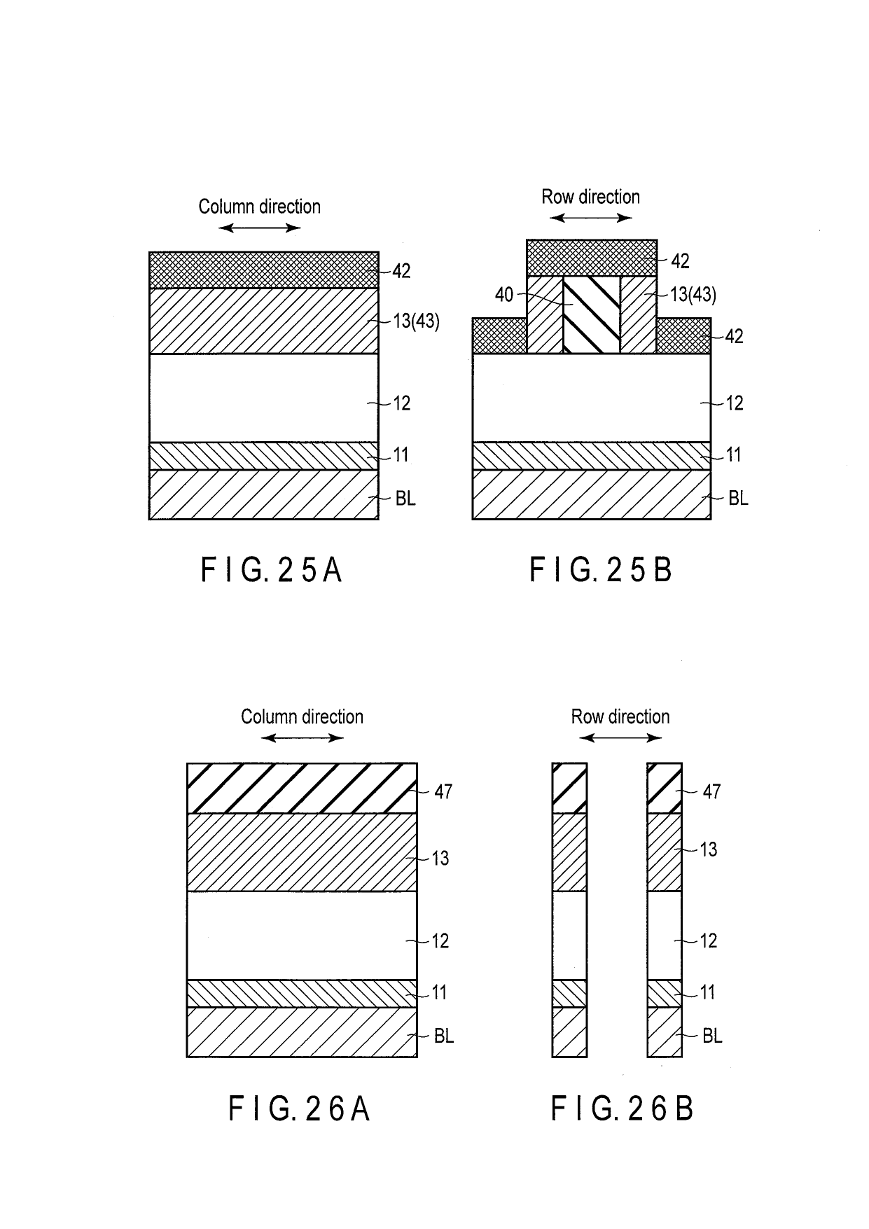

As shown in FIGS. 25A and 25B, the metal layer 44 is annealed. This annealing is performed at a temperature of, for example, 350° C. (inclusive) to 500° C. (inclusive), and preferably, about 400° C. for 1 hr. The non-impurity regions 43 are thus impregnated with Ag contained in the metal layer 44 so that upper electrodes 13 are formed in the sidewall member 41 formed on the side surfaces of the core member 40. That is, the upper electrodes 13 containing Ag and Si are formed on the resistance change layer 12 along the column direction. At this time, the impurity regions 42 are not impregnated with Ag.

The metal layer 44 remaining on the upper electrodes 13 and the impurity regions 42 is removed by wet etching using hydrofluoric acid such as DHF. At this time, the Ag contained in the upper electrodes 13 is not removed because it is impregnated in the a-Si layer (sidewall member 41). As a result, only the metal layer 44 can selectively be removed.

As shown in FIGS. 26A and 26B, the impurity regions 42 and the core member 40 are removed by, for example, RIE or wet etching. The upper electrodes 13 having a size unresolvable by lithography are thus formed by the sidewall transfer technology.

After that, a hard mask (sidewall member) 47 containing, for example, SiN is formed on the upper electrodes 13 by the sidewall transfer technology. The resistance change layer 12, the lower electrode 11, and the bit line BL are processed by, for example, RIE using the hard mask (sidewall member) 47 as a mask. The resistance change layer 12, the lower electrode 11, and the bit line BL are thus divided along the column direction. At this time, the upper electrodes 13 need not be processed by RIE.

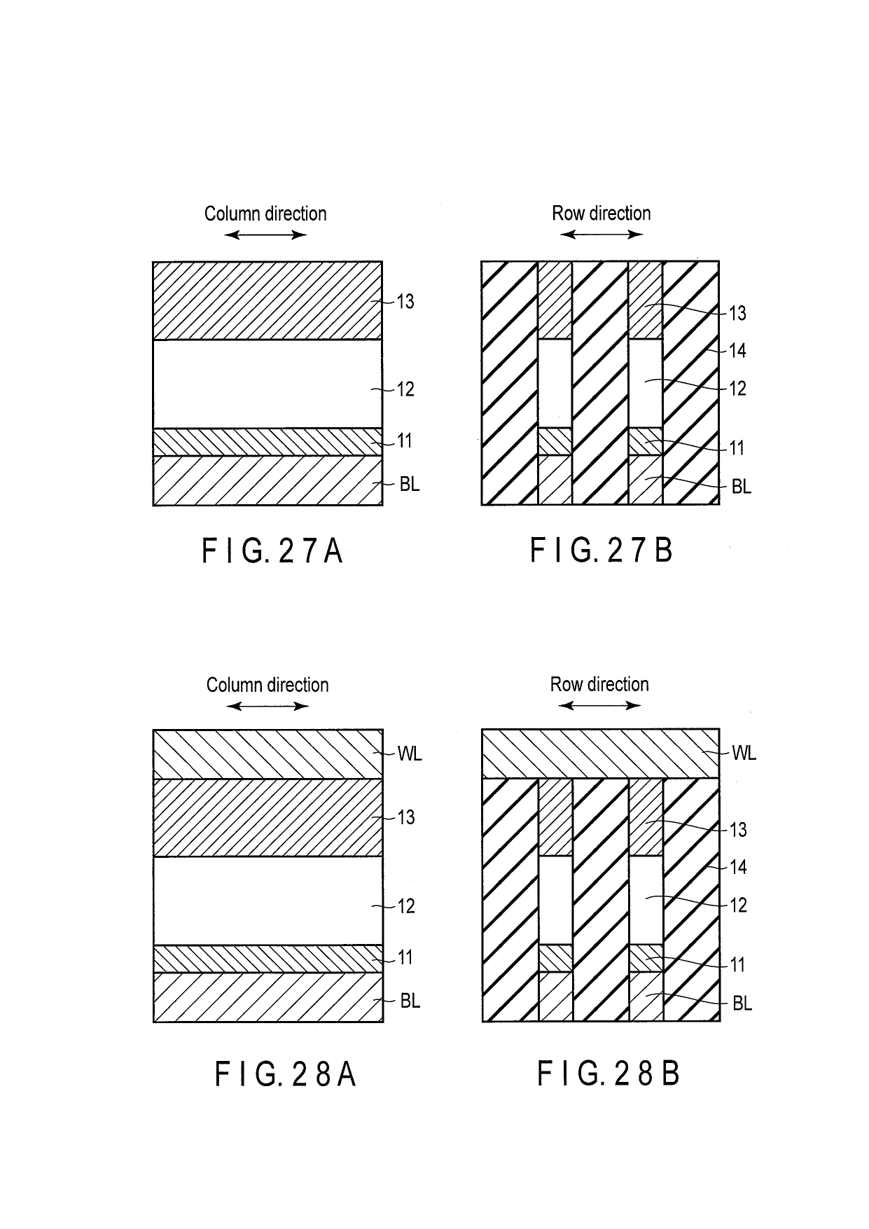

As shown in FIGS. 27A and 27B, insulating films 14 containing, for example, SiO₂ are formed between the upper electrodes 13, the resistance change layers 12, the lower electrodes 11, and the bit lines BL, which are divided along the column direction.

As shown in FIGS. 28A and 28B, a word line WL is formed on the upper electrodes 13 and the insulating films 14 by CVD or ALD.

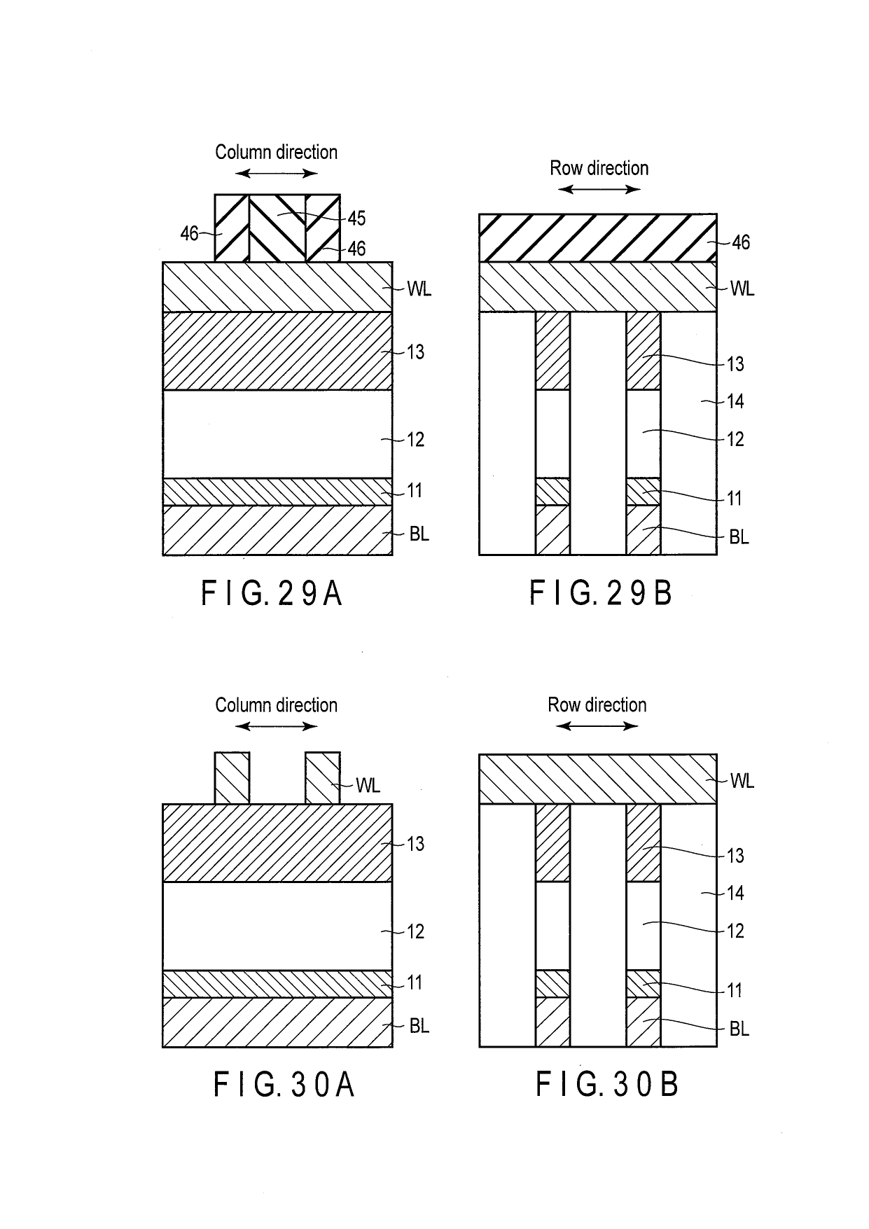

As shown in FIGS. 29A and 29B, a core member 45 for sidewall transfer is formed on the word line WL.

More specifically, the core member 45 is formed on the entire surface of the word line WL and then patterned by RIE or the like using a resist (not shown) as a mask. The core member 45 is patterned so as to run along the row direction. The core member 45 contains, for example, SiO₂.

Next, sidewall members 46 are formed on the side surfaces of the core member 45. More specifically, the sidewall member 46 is formed on the entire surface by, for example, CVD or ALD. After that, the sidewall member 46 is removed from the upper surface of the word line WL and the upper surface of the core member 45 so as to remain only on the side surfaces of the core member 45. The film thickness of the sidewall member 46 is, for example, about 1/2 the column-direction size of the core member 45. The sidewall member 46 contains, for example, SiN.

As shown in FIGS. 30A and 30B, after the core member 45 is removed, the word line WL is processed by, for example, RIE using the sidewall members 46 as a mask. The word line WL is thus divided along the row direction. At this time, the upper electrodes 13 are not processed by RIE. After that, the sidewall members 46 are removed.

Next, as shown in FIGS. 20A and 20B, insulating films 28 containing, for example, SiO₂ are formed between the word lines WL divided along the row direction.

In the above-described way, the memory cell MC and the cross point memory structure according to the third embodiment are formed.

In this embodiment, the upper electrodes 13, the resistance change layers 12, and the lower electrodes 11 are formed to run in the column direction together with the bit lines BL. However, the embodiment is not limited to this. That is, only the bit lines BL may be formed along the column direction, and after that, the upper electrodes 13, the resistance change layers 12, and the lower electrodes 11 may be formed to run in the row direction together with the word lines WL. More specifically, the core member 40 may be formed to run along the row direction, and the upper electrodes 13 containing Si and Ag may be formed on its side surfaces.

### [Effects]

According to the third embodiment, it is possible to obtain the same effects as in the first embodiment.

Additionally, in the third embodiment, the sidewall members 41 (non-impurity regions 43) containing a-Si are formed on the side surfaces of the core member 40. After that, the metal layer 44 containing Ag is formed on the sidewall members 41 and annealed to impregnate the non-impurity regions 43 with Ag, thereby forming the upper electrodes 13 on the side surfaces of the core member 40. That is, the Ag electrodes are formed by the sidewall transfer technology. This makes it possible to form Ag electrodes having a fine pattern unresolvable by lithography.

### Fourth Embodiment

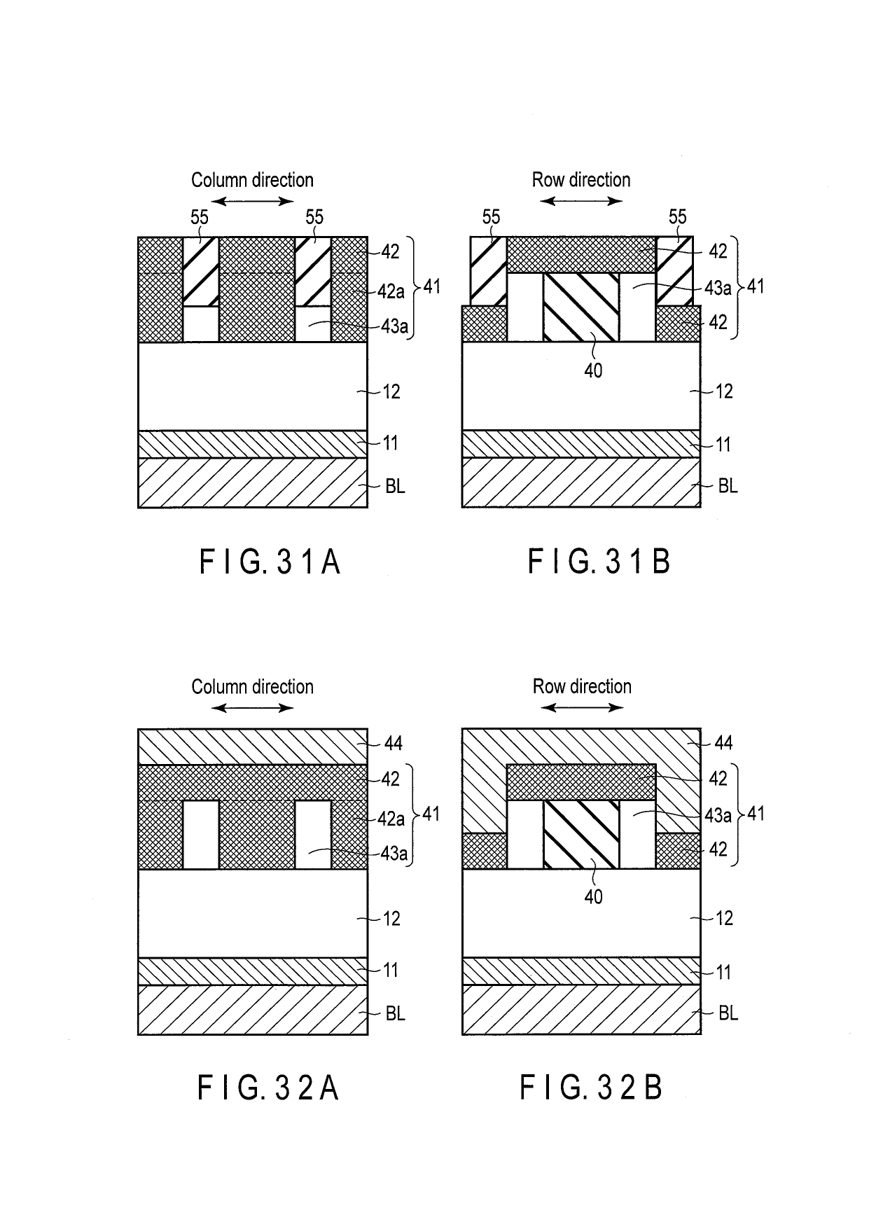

A semiconductor device according to the fourth embodiment will be described with reference to FIGS. 31A, 31B, 32A, 32B, 33A, 33B, 34A, 34B, 35A, 35B, 36A, 36B, 37A, 37B, 38A, 38B, 39A, 39B, 40A, and 40B.

The fourth embodiment is a modification of the third embodiment, in which sidewall members 41 containing a-Si are selectively impregnated with Ag to form upper electrodes 13. Hence, the semiconductor device according to the fourth embodiment has the same structure as that of the first embodiment and has sizes unresolvable by lithography in the column direction and the row direction. The fourth embodiment will be described below in detail. Note that in the fourth embodiment, a description of the same points as in the above-described embodiments will be omitted, and different points will mainly be explained.

### [Manufacturing Method]

A method of manufacturing the semiconductor device according to the fourth embodiment will be described below with reference to FIGS. 31A, 31B, 32A, 32B, 33A, 33B, 34A, 34B, 35A, 35B, 36A, 36B, 37A, 37B, 38A, 38B, 39A, 39B, 40A, and 40B.

FIGS. 31A, 31B, 32A, 32B, 33A, 33B, 34A, 34B, 35A, 35B, 36A, 36B, 37A, 37B, 38A, 38B, 39A, 39B, 40A, and 40B are sectional views showing steps in the manufacture of a memory cell MC according to the fourth embodiment. More specifically, FIGS. 31A, 32A, 33A, 34A, 35A, 36A, 37A, 38A, 39A, and 40A are sectional views taken along a line A-A in FIG. 1. FIGS. 31B, 32B, 33B, 34B, 35B, 36B, 37B, 38B, 39B, and 40B are sectional views taken along a line B-B in FIG. 1.

First, the processes shown in FIGS. 21A, 21B, 22A, 22B, 23A, and 23B are performed, as in the third embodiment. That is, a sidewall member 41 is partially doped with an impurity by uniform ion implantation in a direction perpendicular to the surface of a semiconductor substrate 10. Impurity regions 42 with the impurity diffused are thus formed in the sidewall member 41 formed on the upper surface of a resistance change layer 12 and the upper surface of a core member 40. Non-impurity regions 43 having no impurity diffused are formed in the sidewall member 41 formed on the side surfaces of the core member 40.

Next, as shown in FIGS. 31A and 31B, sidewall members 55 are formed by the sidewall transfer technology on part (part of the non-impurity regions 43) of the surface of the sidewall member 41 formed on the side surfaces of the core member 40. The sidewall members 55 contain, for example, SiN or SiO₂.

After that, the non-impurity regions 43 are partially doped with an impurity by uniform ion implantation in a direction oblique to the surface of the semiconductor substrate 10 (0°<θ<90° with respect to the surface of the semiconductor substrate 10). More specifically, the regions of the non-impurity regions 43 that are not covered with the sidewall members 55 are doped with the impurity to form impurity regions 42a. The regions of the non-impurity regions 43 that are covered with the sidewall members 55 are not doped with the impurity to form non-impurity regions 43a. After that, the sidewall members 55 are removed.

Note that the sidewall members 55 may be formed before formation of the impurity regions 42 shown in FIGS. 23A and 23B. At this time, formation of the impurity regions 42 and 42a by ion implantation may be performed continuously.

Next, as shown in FIGS. 32A and 32B, a metal layer 44 is formed on the sidewall member 41 by, for example, PVD such as sputtering. That is, the metal layer 44 is formed on the impurity regions 42 and 42a and the non-impurity regions 43a. The metal layer 44 contains a low-volatile metal material, for example, at least one of Ag and Cu. The metal layer 44 may contain Ag₂S or Cu₂S. The following description will be made assuming that the metal layer 44 contains Ag.

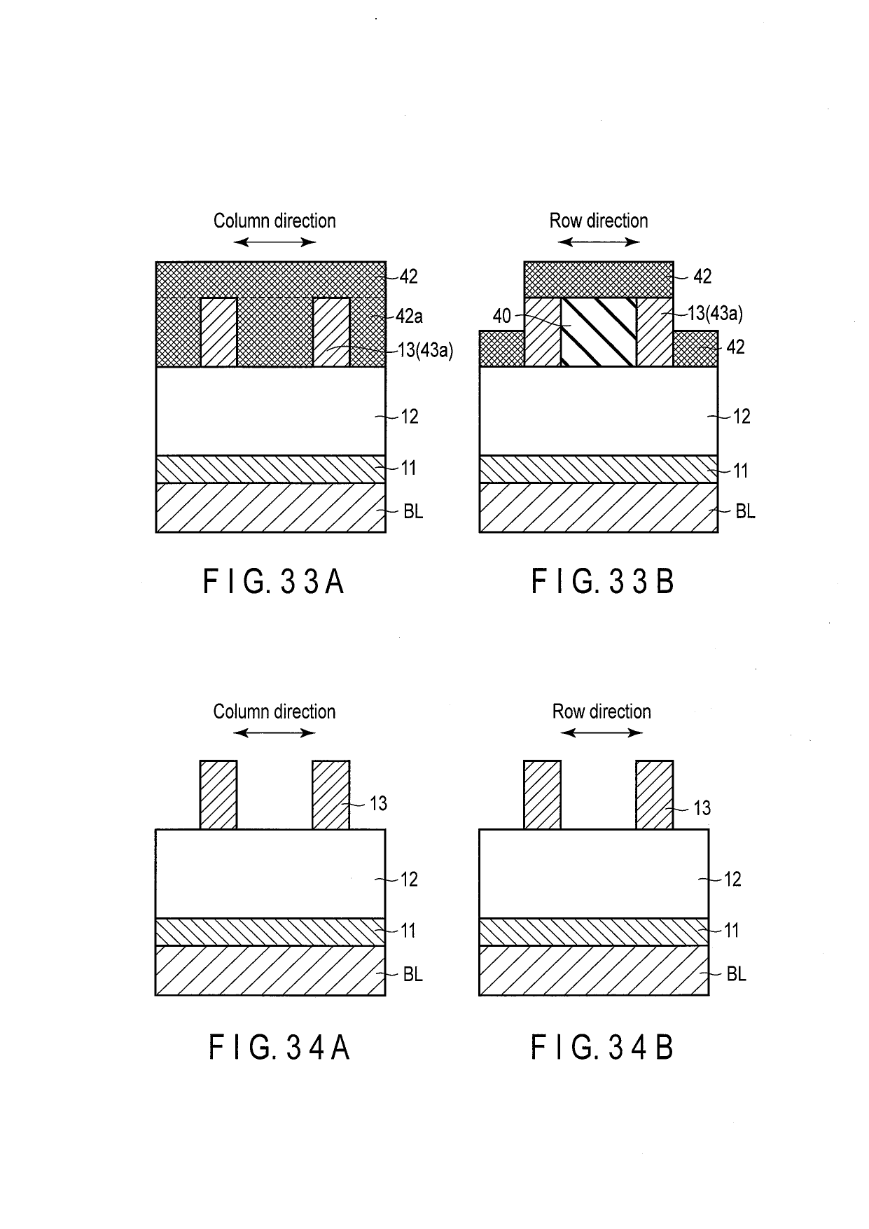

As shown in FIGS. 33A and 33B, the metal layer 44 is annealed. This annealing is performed at a temperature of, for example, 350° C. (inclusive) to 500° C. (inclusive), and preferably, about 400° C. for 1 hr. The non-impurity regions 43a are thus impregnated with Ag contained in the metal layer 44 so that upper electrodes 13 are formed in part of the sidewall member 41 formed on the side surfaces of the core member 40. That is, the upper electrodes 13 containing Ag and Si are divisionally formed along the column direction and the row direction. At this time, the impurity regions 42 and 42a are not impregnated with Ag.

The metal layer 44 remaining on the upper electrodes 13 and the impurity regions 42 and 42a is removed by wet etching using hydrofluoric acid such as DHF. At this time, the Ag contained in the upper electrodes 13 is not removed because it is impregnated in the a-Si layer (sidewall member 41). As a result, only the metal layer 44 can selectively be removed.

As shown in FIGS. 34A and 34B, the impurity regions 42 and 42a and the core member 40 are removed by, for example, RIE or wet etching. The upper electrodes 13 having a size unresolvable by lithography are thus formed by the sidewall transfer technology.

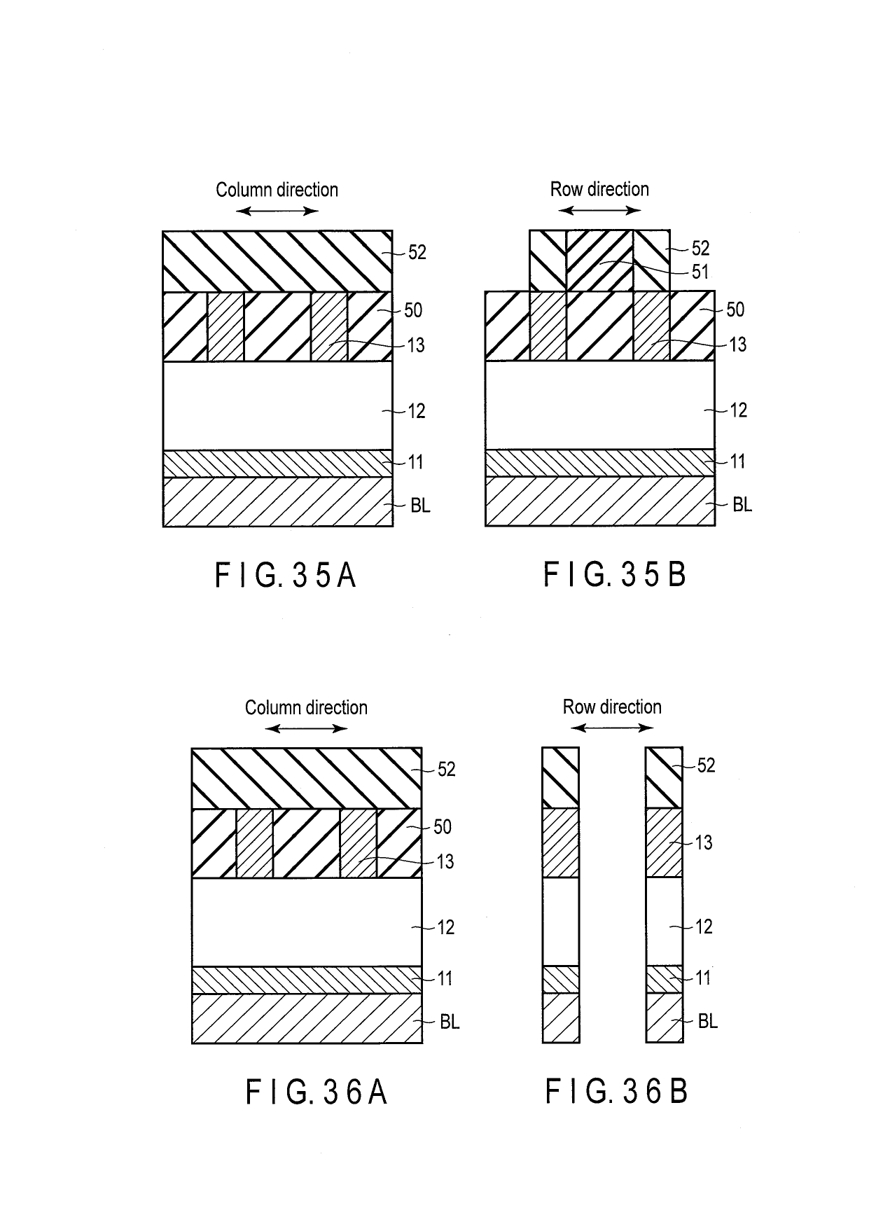

As shown in FIGS. 35A and 35B, insulating films 50 containing, for example, SiO₂ are formed on the resistance change layer 12 between the upper electrodes 13 divided along the column direction and the row direction.

A core member 51 for sidewall transfer is formed on the insulating film 50 and patterned so as to run along the column direction. The core member 51 contains, for example, SiO₂.

Next, sidewall members 52 are formed on the side surfaces of the core member 51. The sidewall members 52 run along the column direction. The sidewall members 52 contain, for example, SiN. In the row direction, the sidewall member 52 has almost the same size as that of the upper electrode 13 and is formed at the same position as the upper electrode 13. In other words, the sidewall members 52 overlap the upper electrodes 13 in the row direction.

As shown in FIGS. 36A and 36B, after the core member 51 is removed, the insulating films 50, the resistance change layer 12, a lower electrode 11, and a bit line BL are processed by, for example, RIE using the sidewall members 52 as a mask. The insulating films 50, the resistance change layer 12, the lower electrode 11, and the bit line BL are thus divided along the column direction. The upper electrodes 13 are not processed at this time because they are divided in advance along the column direction and overlap the sidewall members 52 in the row direction. In other words, the upper electrodes 13 need not be processed by RIE.

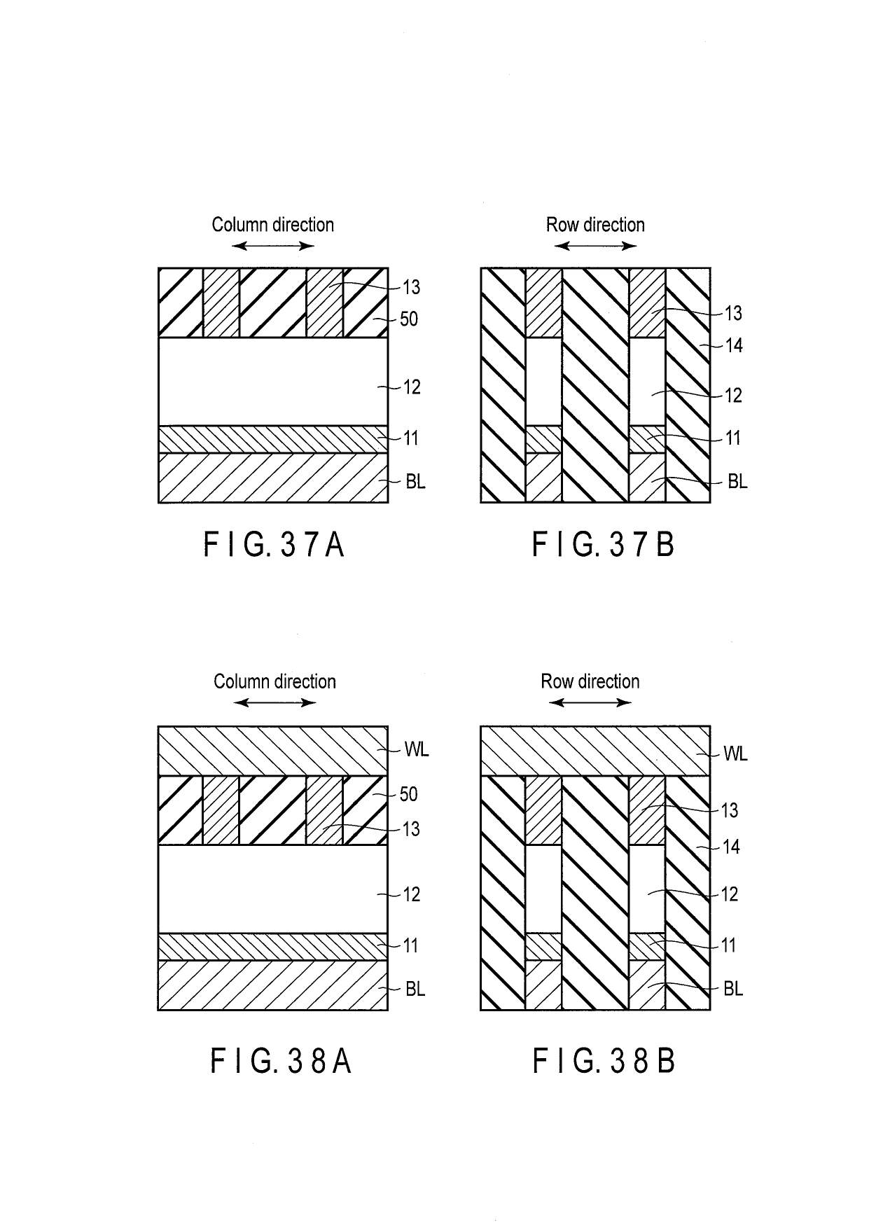

As shown in FIGS. 37A and 37B, the sidewall members 52 are removed. After that, insulating films 14 containing, for example, SiO₂ are formed between the upper electrodes 13, the insulating films 50, the resistance change layers 12, the lower electrodes 11, and the bit lines BL, which are divided along the column direction.

As shown in FIGS. 38A and 38B, a word line WL is formed on the upper electrodes 13, insulating films 50, and the insulating films 14 by CVD or ALD.

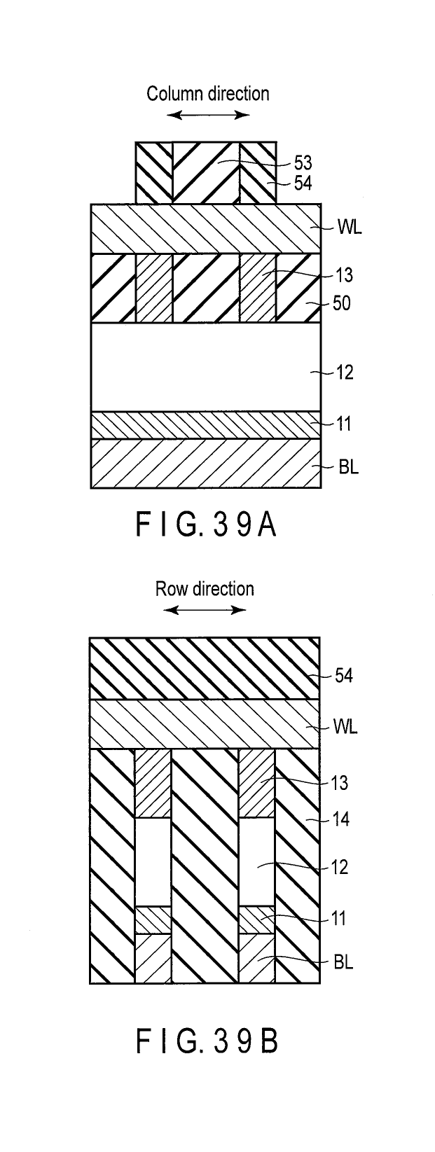

As shown in FIGS. 39A and 39B, a core member 53 for sidewall transfer is formed on the word line WL and patterned to run along the row direction. The core member 53 contains, for example, SiO₂.

Next, sidewall members 54 are formed on the side surfaces of the core member 53. The sidewall members 54 run along the row direction. The sidewall members 54 contain, for example, SiN. In the column direction, the sidewall member 54 has almost the same size as that of the upper electrode 13 and is formed at the same position as the upper electrode 13. In other words, the sidewall members 54 overlap the upper electrodes 13 in the column direction.

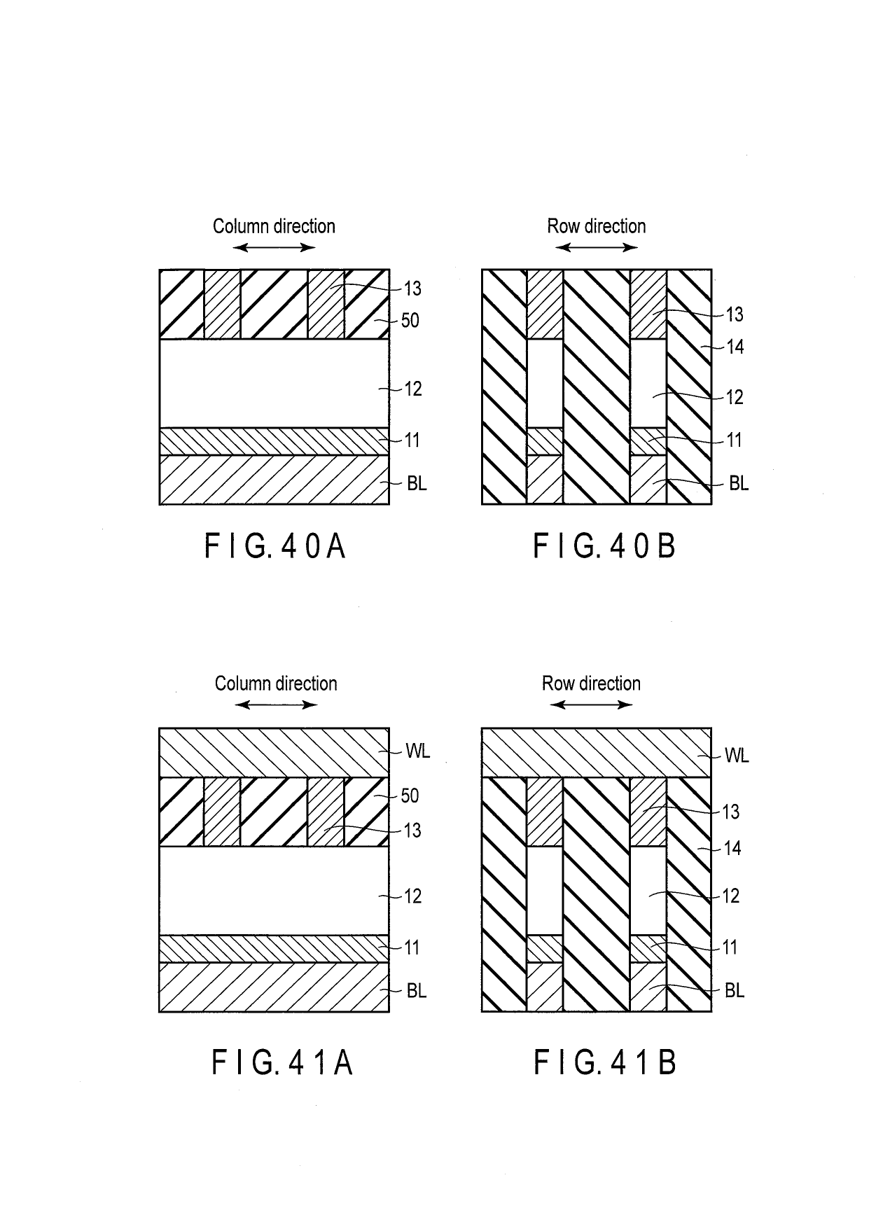

As shown in FIGS. 40A and 40B, after the core member 53 is removed, the word line WL, the insulating films 50, the resistance change layers 12, and the lower electrodes 11 are processed by, for example, RIE using the sidewall members 54 as a mask. The word line WL, the insulating films 50, the resistance change layers 12, and the lower electrodes 11 are thus divided along the row direction. The upper electrodes 13 are not processed at this time because they are divided in advance along the row direction and overlap the sidewall members 54 in the column direction. In other words, the upper electrodes 13 need not be processed by RIE.

Next, as shown in FIGS. 2A and 2B, the sidewall members 54 are removed. After that, insulating films 28 containing, for example, SiO₂ are formed between the word lines WL, the upper electrodes 13, the resistance change layers 12, and the lower electrodes 11, which are divided along the row direction.

In the above-described way, the memory cell MC and the cross point memory structure according to the fourth embodiment are formed.

### [Effects]

According to the fourth embodiment, it is possible to obtain the same effects as in the third embodiment.

### Fifth Embodiment

A semiconductor device according to the fifth embodiment will be described with reference to FIGS. 41A, 41B, 42A, 42B, 43A, 43B, 44A, 44B, 45A, 45B, 46A, 46B, 47A, 47B, 48A, 48B, 49A, 49B, 50A, and 50B. In the fifth embodiment, the upper portion of an a-Si layer 67 is partially formed by a sidewall transfer technology into a fine pattern unresolvable by lithography. After that, the portions are impregnated with Ag to form upper electrodes 13, and a resistance change layer 12 is formed in the lower portion of the a-Si layer 67. The fifth embodiment will be described below in detail. Note that in the fifth embodiment, a description of the same points as in the above-described embodiments will be omitted, and different points will mainly be explained.

### [Manufacturing Method]

A method of manufacturing the semiconductor device according to the fifth embodiment will be described below with reference to FIGS. 41A, 41B, 42A, 42B, 43A, 43B, 44A, 44B, 45A, 45B, 46A, 46B, 47A, 47B, 48A, 48B, 49A, 49B, 50A, and 50B.

FIGS. 41A, 41B, 42A, 42B, 43A, 43B, 44A, 44B, 45A, 45B, 46A, 46B, 47A, 47B, 48A, 48B, 49A, 49B, 50A, and 50B are sectional views showing steps in the manufacture of a memory cell MC according to the fifth embodiment. More specifically, FIGS. 41A, 42A, 43A, 44A, 45A, 46A, 47A, 48A, 49A, and 50A are sectional views taken along a line A-A in FIG. 1. FIGS. 41B, 42B, 43B, 44B, 45B, 46B, 47B, 48B, 49B, and 50B are sectional views taken along a line B-B in FIG. 1.

First, as shown in FIGS. 41A and 41B, a bit line BL is formed on an insulating film on a semiconductor substrate 10 by, for example, CVD or ALD. A lower electrode 11 is formed on the bit line BL. After that, an a-Si layer 67 is formed on the lower electrode 11 by, for example, CVD or ALD.

Next, a core member 60 for sidewall transfer is formed on the a-Si layer 67 and patterned so as to run along the column direction. The core member 60 contains, for example, SiO₂. After that, sidewall members 61 are formed on the side surfaces of the core member 60. The sidewall members 61 run along the column direction. The sidewall members 61 contain, for example, SiN.

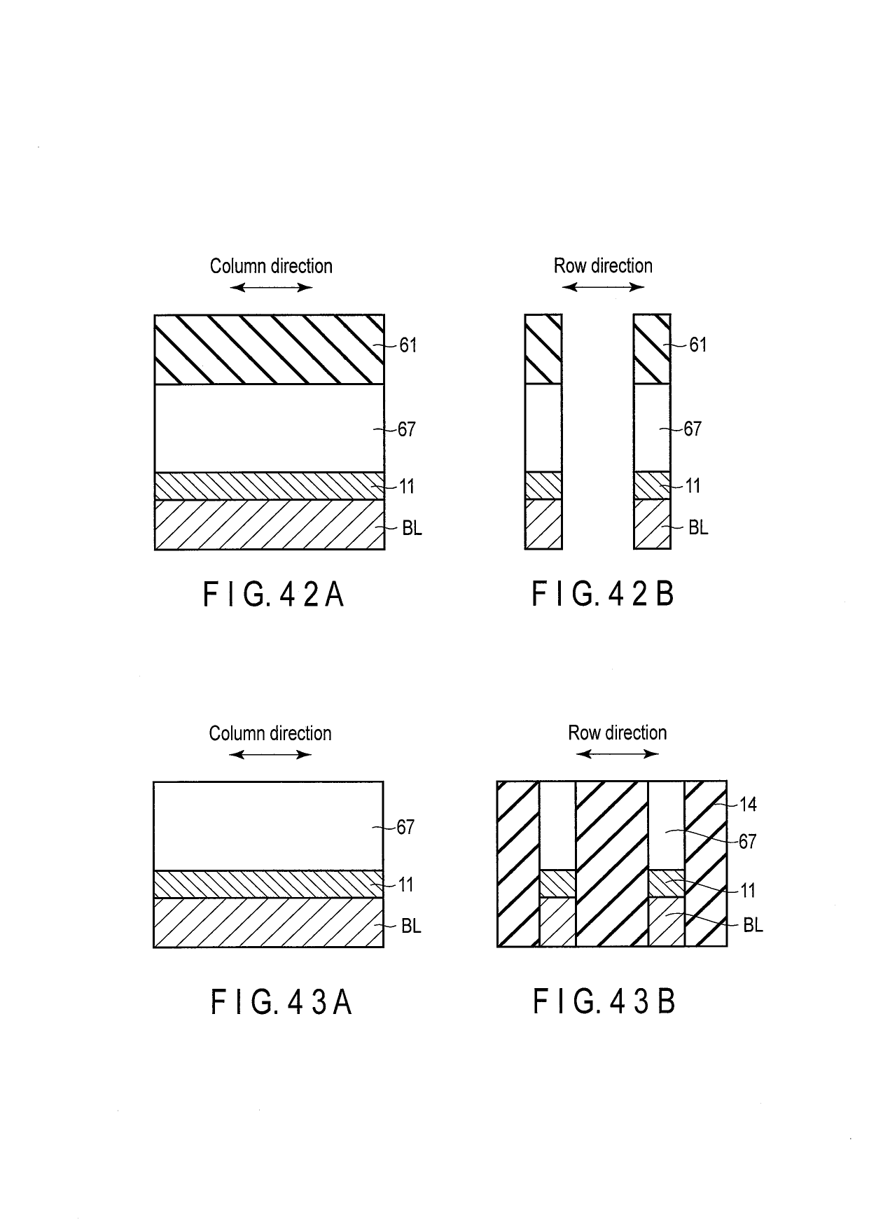

As shown in FIGS. 42A and 42B, after the core member 60 is removed, the a-Si layer 67, the lower electrode 11, and the bit line BL are processed by, for example, RIE using the sidewall members 61 as a mask. The a-Si layer 67, the lower electrode 11, and the bit line BL are thus divided along the column direction.

As shown in FIGS. 43A and 43B, the sidewall members 61 are removed. After that, insulating films 14 containing, for example, SiO₂ are formed between the a-Si layers 67, the lower electrodes 11, and the bit lines BL, which are divided along the column direction.

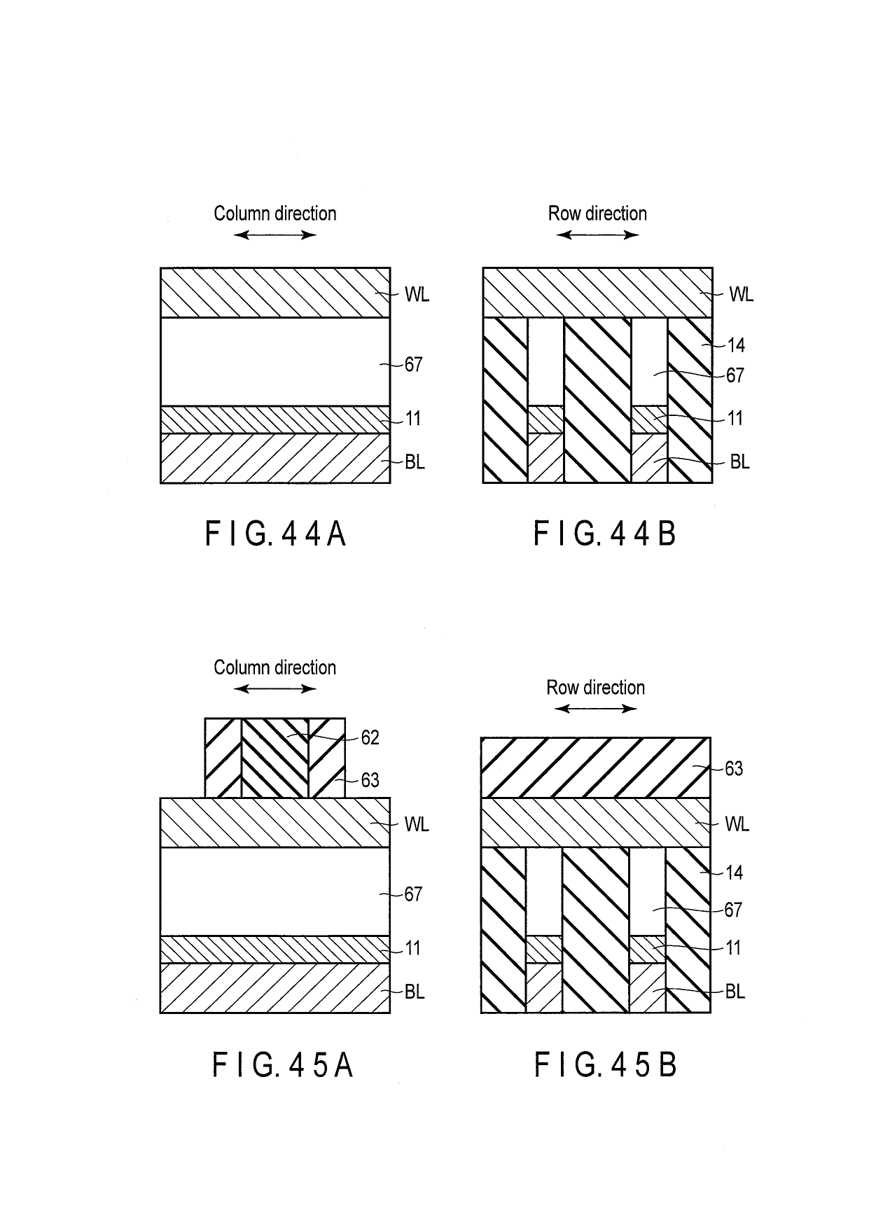

As shown in FIGS. 44A and 44B, a word line WL is formed on the a-Si layers 67 and the insulating films 14 by CVD or ALD.

As shown in FIGS. 45A and 45B, a core member 62 for sidewall transfer is formed on the word line WL and patterned so as to run along the row direction. The core member 62 contains, for example, SiO₂. After that, sidewall members 63 are formed on the side surfaces of the core member 62. The sidewall members 63 run along the row direction. The sidewall members 63 contain, for example, SiN.

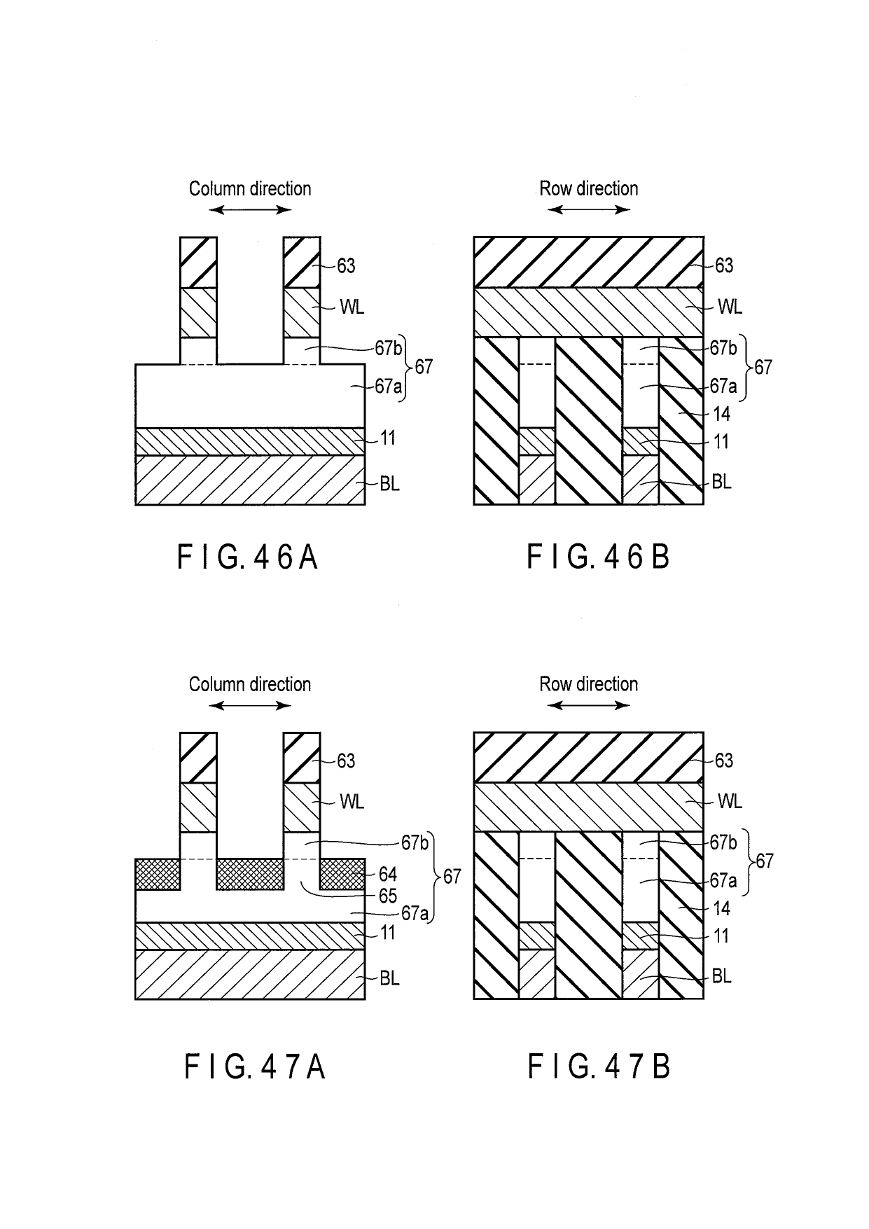

As shown in FIGS. 46A and 46B, after the core member 62 is removed, the word line WL and the a-Si layers 67 are processed by, for example, RIE using the sidewall members 63 as a mask. At this time, the a-Si layers 67 are processed halfway. The word line WL is thus divided along the row direction. On the other hand, part of the upper portion of each a-Si layer 67 is divided along the row direction. In other words, each a-Si layer 67 includes a first portion 67a on the lower side divided along the column direction and a second portion 67b on the upper side divided along the column direction and the row direction.

As shown in FIGS. 47A and 47B, the upper portion of the first portion 67a is partially doped with an impurity by uniform ion implantation in a direction perpendicular to the surface of the semiconductor substrate 10. Impurity regions 64 with the impurity diffused are thus formed in the upper portion of the first portion 67a. More specifically, the impurity regions 64 are formed in the upper portion of the first portion 67a with the upper surface exposed. On the other hand, non-impurity regions 65 having no impurity diffused are formed in the upper portion of the first portion 67a and the second portions 67b.

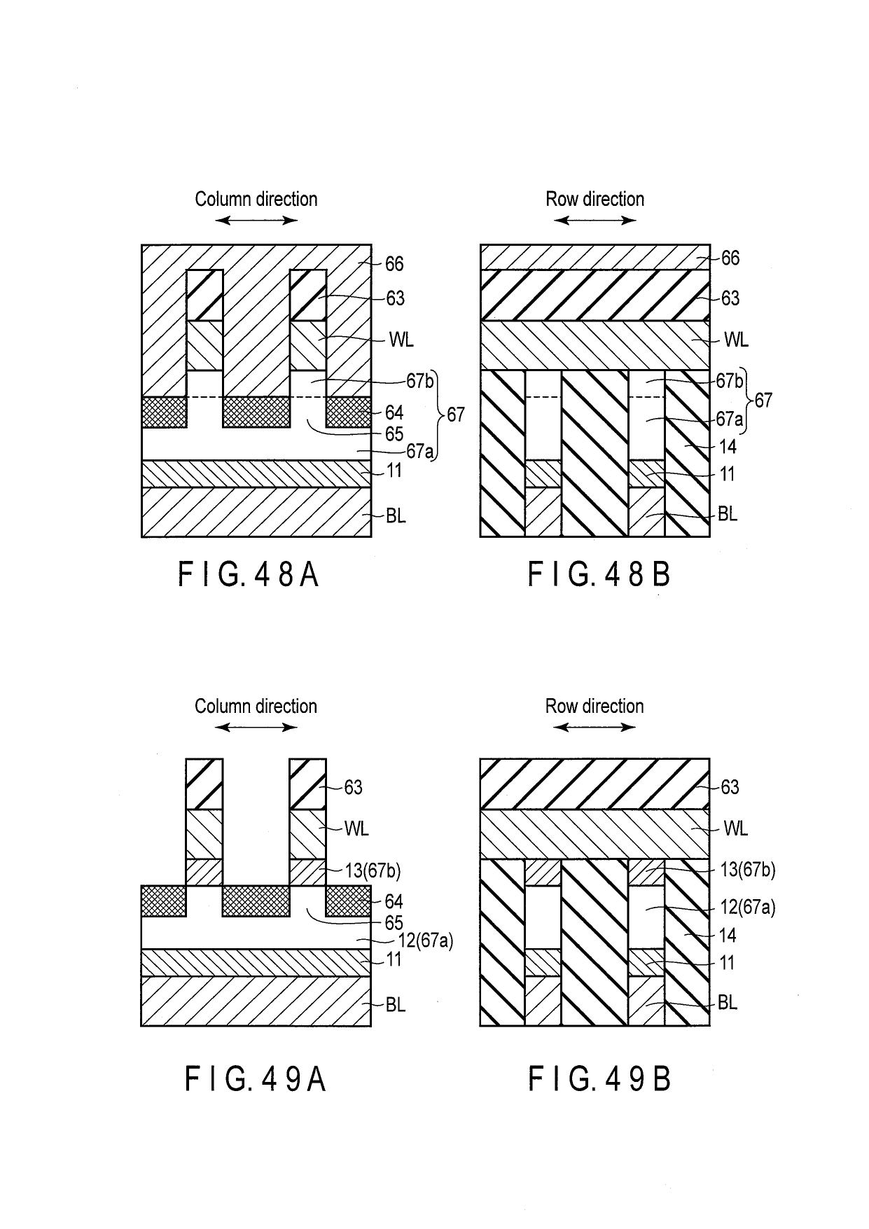

Next, as shown in FIGS. 48A and 48B, a metal layer 66 is formed on the entire surface by, for example, PVD such as sputtering. The metal layer 66 contains a low-volatile metal material, for example, at least one of Ag and Cu. The metal layer 66 may contain Ag₂S or Cu₂S. The following description will be made assuming that the metal layer 66 contains Ag.

As shown in FIGS. 49A and 49B, the metal layer 66 is annealed. This annealing is performed at a temperature of, for example, 350° C. (inclusive) to 500° C. (inclusive), and preferably, about 400° C. for 1 hr. The non-impurity regions 65 (second portions 67b) are thus impregnated with Ag contained in the metal layer 66 so that upper electrodes 13 are formed in the second portions 67b. That is, the upper electrodes 13 containing Ag and Si are formed along the column direction and the row direction. At this time, the impurity regions 64 are not impregnated with Ag. The non-impurity regions 65 in the first portions 67a that are not impregnated with Ag change to resistance change layers 12. Note that the non-impurity regions 65 in the first portions 67a may partially be impregnated with Ag.

The remaining metal layer 66 is removed by wet etching using hydrofluoric acid such as DHF. At this time, the Ag contained in the upper electrodes 13 is not removed because it is impregnated in the second portions 67b of the a-Si layers 67. As a result, only the metal layer 66 can selectively be removed.

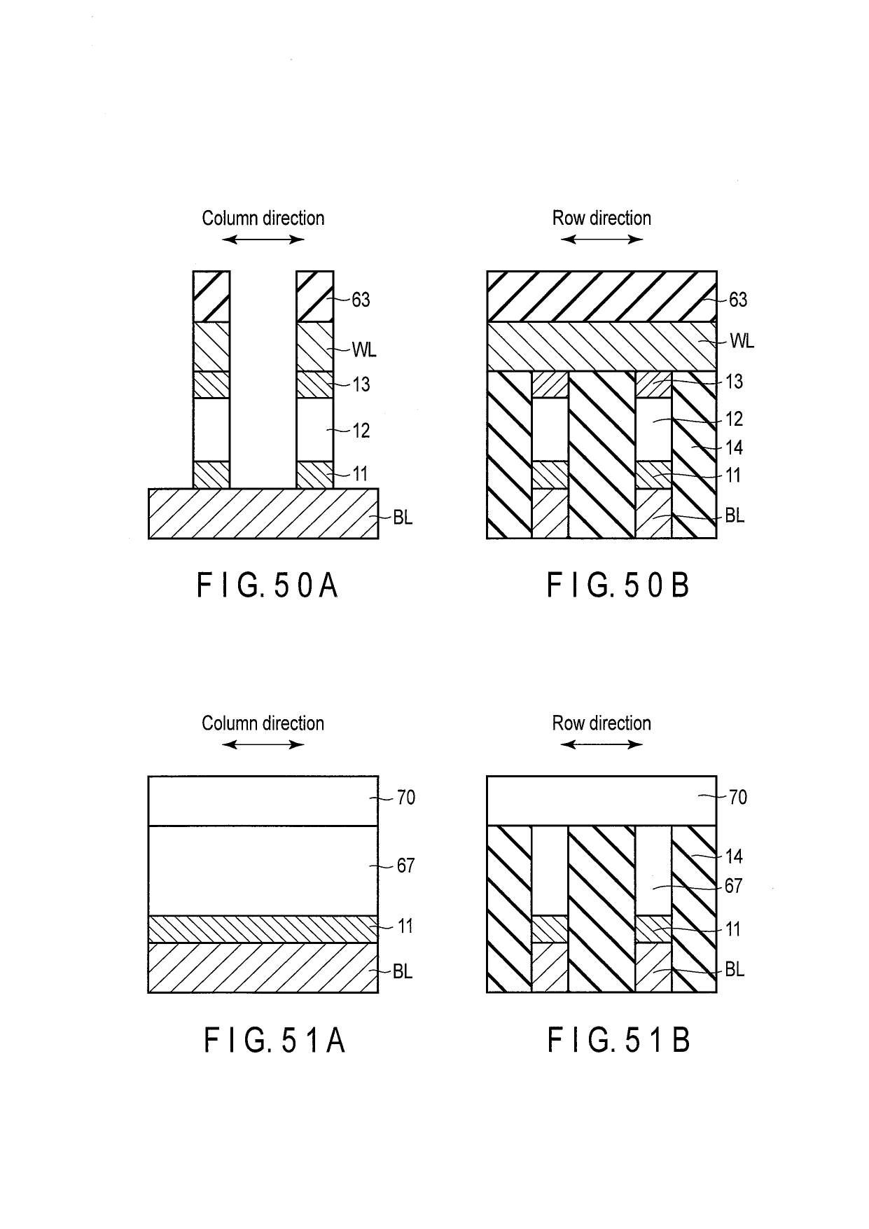

As shown in FIGS. 50A and 50B, the resistance change layers 12 (first portions 67a) and the lower electrodes 11 are processed by, for example, RIE using the sidewall members 63 as a mask. The resistance change layers 12 and the lower electrodes 11 are thus divided along the row direction. The upper electrodes 13 are not processed at this time because they are divided in advance along the row direction and overlap the sidewall members 63 in the column direction. In other words, the upper electrodes 13 need not be processed by RIE.

Next, as shown in FIGS. 2A and 2B, the sidewall members 63 are removed. After that, insulating films 28 containing, for example, SiO₂ are formed between the word lines WL, the upper electrodes 13, the resistance change layers 12, and the lower electrodes 11, which are divided along the row direction.

In the above-described way, the memory cell MC and the cross point memory structure according to the fifth embodiment are formed.

### [Effects]

According to the fifth embodiment, it is possible to obtain the same effects as in the third embodiment. <Sixth Embodiment>

A semiconductor device according to the sixth embodiment will be described with reference to FIGS. 51A, 51B, 52A, 52B, 53A, 53B, 54A, 54B, 55A, 55B, 56A, 56B, 57A, and 57B. The sixth embodiment is a modification of the fifth embodiment, in which word lines WL are integrated with upper electrodes 13. The sixth embodiment will be described below in detail. Note that in the sixth embodiment, a description of the same points as in the above-described embodiments will be omitted, and different points will mainly be explained.

### [Manufacturing Method]

A method of manufacturing the semiconductor device according to the sixth embodiment will be described below with reference to FIGS. 51A, 51B, 52A, 52B, 53A, 53B, 54A, 54B, 55A, 55B, 56A, 56B, 57A, and 57B.

FIGS. 51A, 51B, 52A, 52B, 53A, 53B, 54A, 54B, 55A, 55B, 56A, 56B, 57A, and 57B are sectional views showing steps in the manufacture of a memory cell MC according to the sixth embodiment. More specifically, FIGS. 51A, 52A, 53A, 54A, 55A, 56A, and 57A are sectional views taken along a line A-A in FIG. 1. FIGS. 51B, 52B, 53B, 54B, 55B, 56B, and 57B are sectional views taken along a line B-B in FIG. 1.

First, the processes shown in FIGS. 41A, 41B, 42A, 42B, 43A, and 43B of the fifth embodiment are performed. That is, insulating films 14 containing, for example, SiO₂ are formed between a-Si layers 67, lower electrodes 11, and bit lines BL, which are divided along the column direction.

Next, as shown in FIGS. 51A and 51B, an a-Si layer 70 is formed on the a-Si layers 67 and the insulating films 14 by CVD or ALD. The a-Si layer 70 becomes word lines WL later.

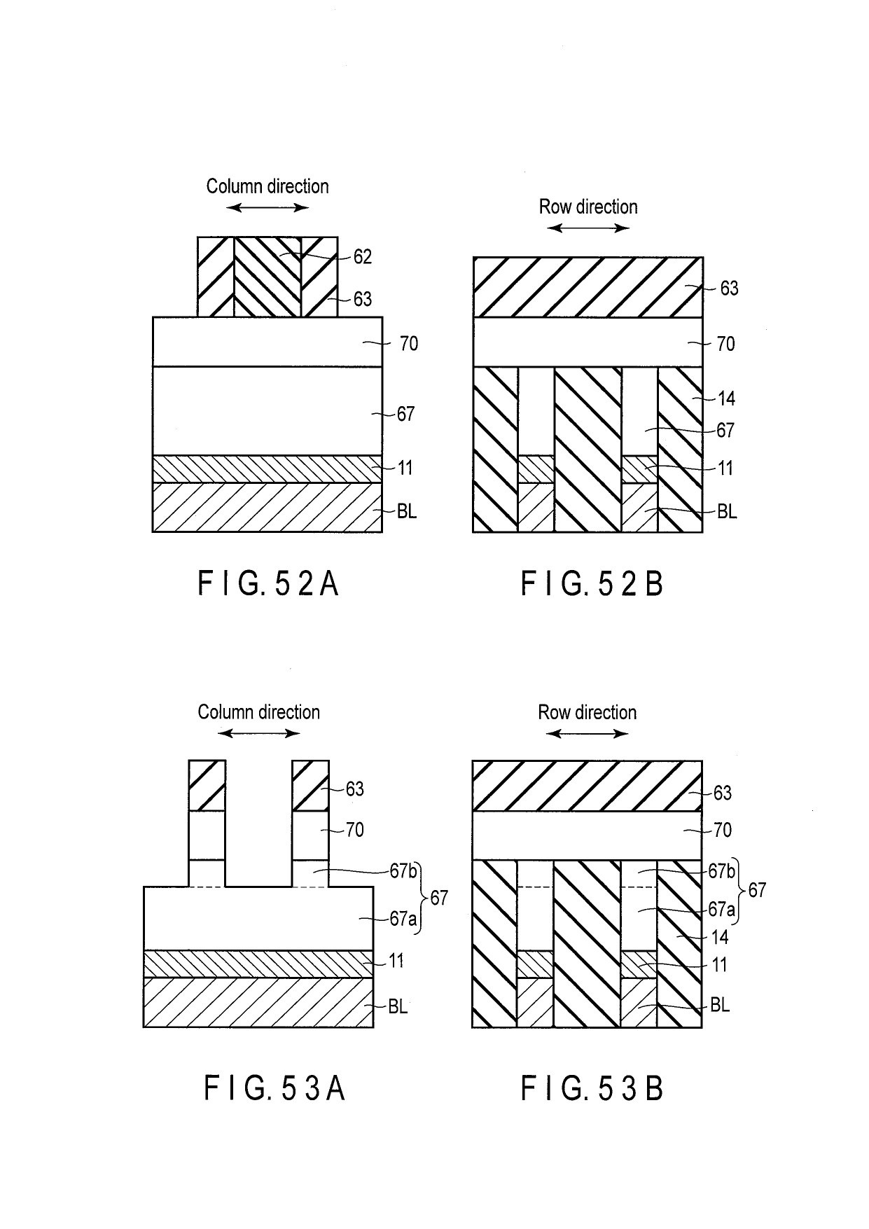

As shown in FIGS. 52A and 52B, a core member 62 for sidewall transfer is formed on the a-Si layer 70 and patterned so as to run along the row direction. The core member 62 contains, for example, SiO₂. After that, sidewall members 63 are formed on the side surfaces of the core member 62. The sidewall members 63 run along the row direction. The sidewall members 63 contain, for example, SiN.

As shown in FIGS. 53A and 53B, after the core member 62 is removed, the a-Si layers 70 and 67 are processed by, for example, RIE using the sidewall members 63 as a mask. At this time, the a-Si layers 67 are processed halfway. The a-Si layer 70 is thus divided along the row direction. On the other hand, part of the upper portion of each a-Si layer 67 is divided along the row direction. In other words, each a-Si layer 67 includes a first portion 67a on the lower side divided along the column direction and a second portion 67b on the upper side divided along the column direction and the row direction.

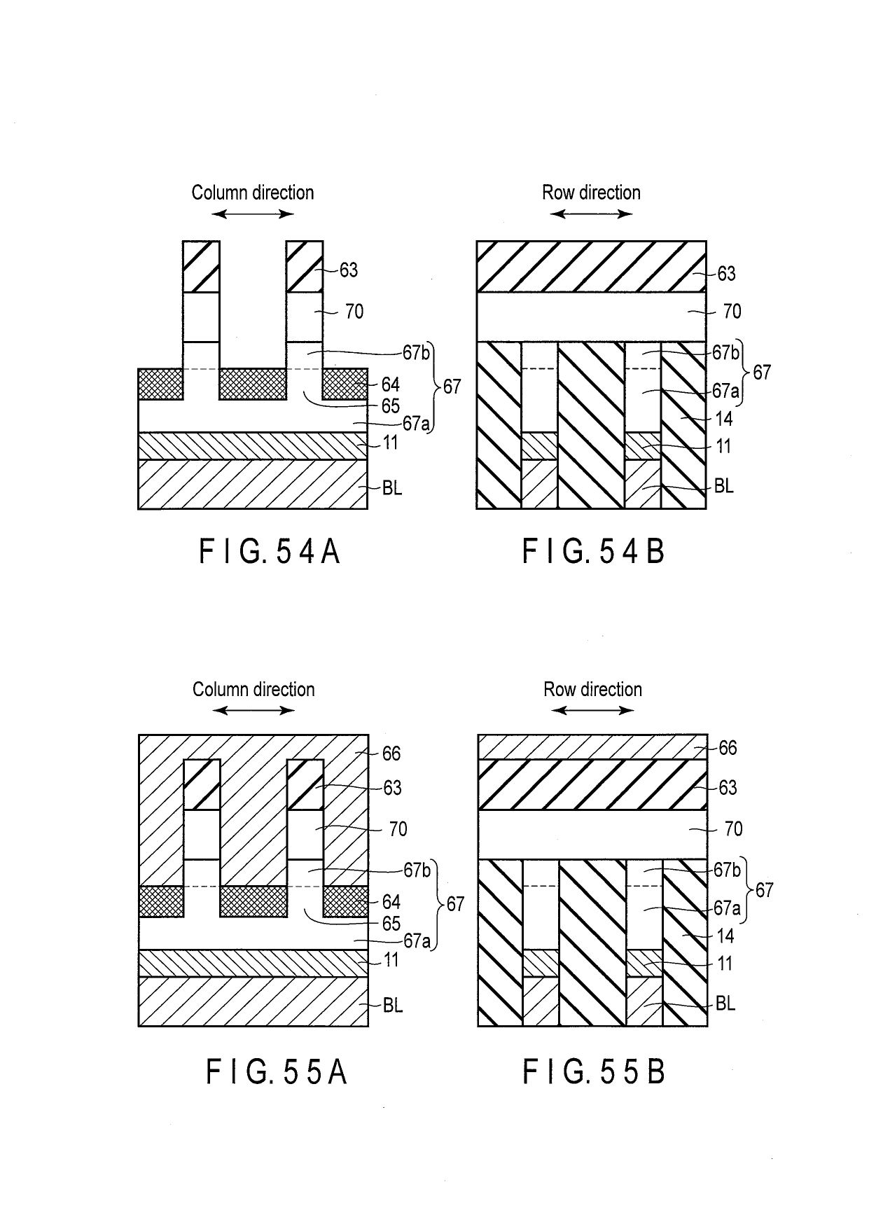

As shown in FIGS. 54A and 54B, the upper portion of the first portion 67a is partially doped with an impurity by uniform ion implantation in a direction perpendicular to the surface of a semiconductor substrate 10. Impurity regions 64 with the impurity diffused are thus formed in the upper portion of the first portion 67a. On the other hand, non-impurity regions 65 having no impurity diffused are formed in the upper portion of the first portion 67a and the second portions 67b.

Next, as shown in FIGS. 55A and 55B, a metal layer 66 is formed on the entire surface by, for example, PVD such as sputtering. The metal layer 66 contains a low-volatile metal material, for example, at least one of Ag and Cu. The metal layer 66 may contain Ag₂S or Cu₂S. The following description will be made assuming that the metal layer 66 contains Ag.

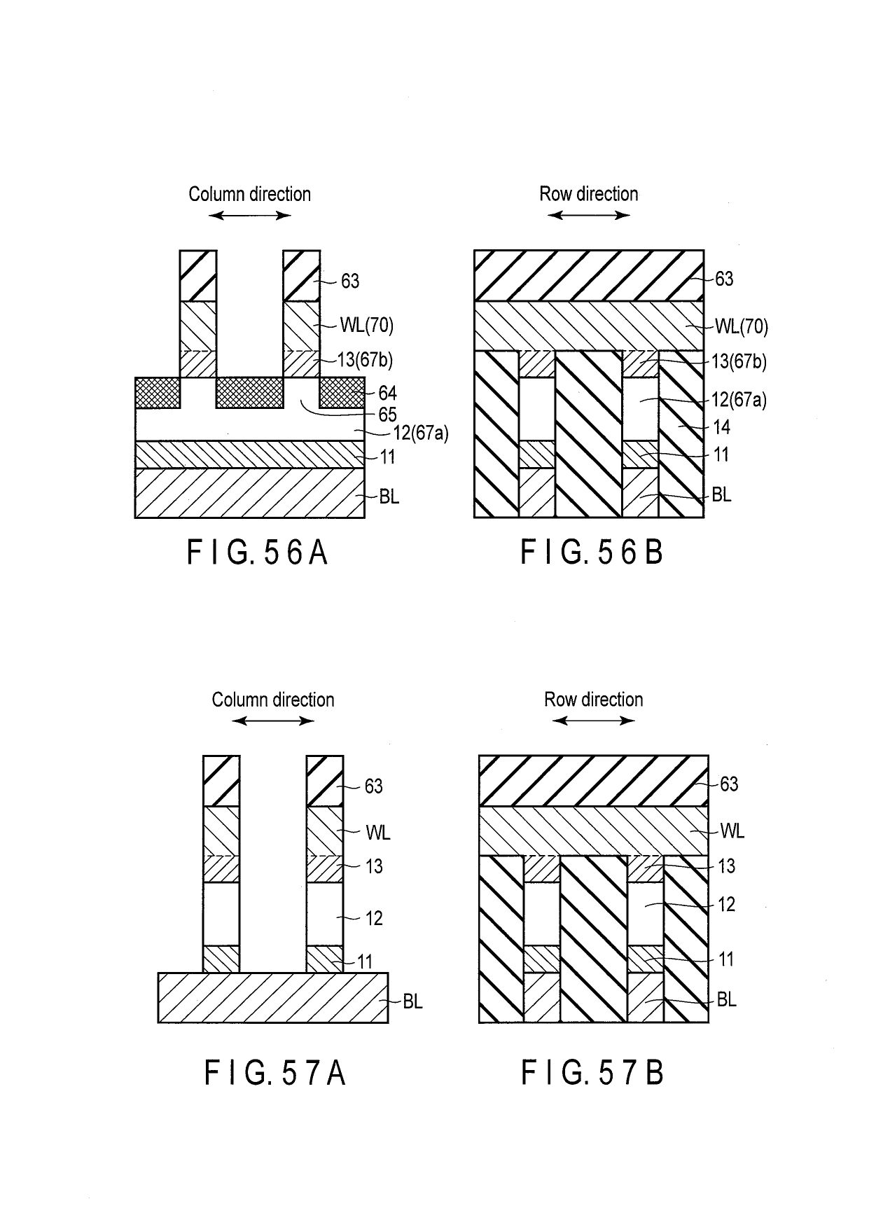

As shown in FIGS. 56A and 56B, the metal layer 66 is annealed. This annealing is performed at a temperature of, for example, 350° C. (inclusive) to 500° C. (inclusive), and preferably, about 400° C. for 1 hr. The non-impurity regions 65 (second portions 67b) are thus impregnated with Ag contained in the metal layer 66 so that upper electrodes 13 are formed in the second portions 67b. That is, the upper electrodes 13 containing Ag and Si are formed along the column direction and the row direction. At this time, the impurity regions 64 are not impregnated with Ag. The non-impurity regions 65 in the first portions 67a that are not impregnated with Ag change to resistance change layers 12. Note that the non-impurity regions 65 in the first portions 67a may partially be impregnated with Ag.

At this time, the a-Si layers 70 are also impregnated with Ag contained in the metal layer 66. The word lines WL containing Ag and Si and running in the row direction are thus formed. That is, the word lines WL and the upper electrodes 13 contain Ag and Si in the same concentrations and are formed integrally.

The remaining metal layer 66 is removed by wet etching using hydrofluoric acid such as DHF. At this time, the Ag contained in the upper electrodes 13 is not removed because it is impregnated in the second portions 67b of the a-Si layers 67. As a result, only the metal layer 66 can selectively be removed.

As shown in FIGS. 57A and 57B, the resistance change layers 12 (first portions 67a) and the lower electrodes 11 are processed by, for example, RIE using the sidewall members 63 as a mask. The resistance change layers 12 and the lower electrodes 11 are thus divided along the row direction.

After that, the sidewall members 63 are removed, and insulating films 28 containing, for example, SiO₂ are formed between the word lines WL, the upper electrodes 13, the resistance change layers 12, and the lower electrodes 11, which are divided along the row direction.

In the above-described way, the memory cell MC and the cross point memory structure according to the sixth embodiment are formed.

### [Effects]

According to the sixth embodiment, it is possible to obtain the same effects as in the fifth embodiment.

### Application Example

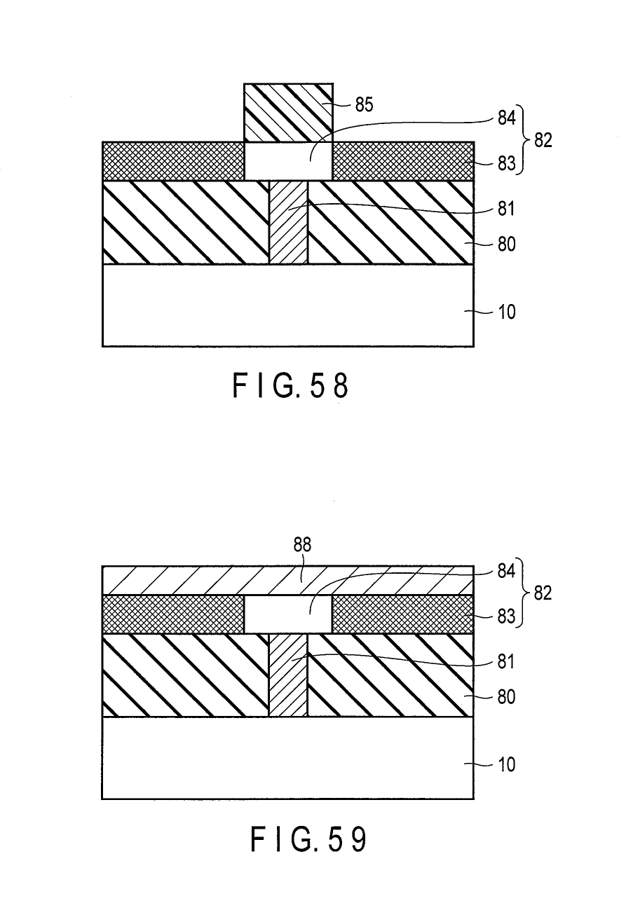

An application example of the metal material hard to undergo the above-described process will be described with reference to FIGS. 58, 59, 60, and 61.

In the first to sixth embodiments, an example has been described in which the metal material hard to process is used as the electrodes of an ReRAM. An example will be explained below in which the metal material hard to process is used as the interconnections of various circuits.

FIGS. 58, 59, 60, and 61 are sectional views showing a method of manufacturing an interconnection structure according to the application example.

Referring to FIG. 58, an interlayer dielectric film 80 containing, for example, SiO₂ is formed on a semiconductor substrate 10. A contact hole is formed in the interlayer dielectric film 80 so as to extend through it. After a barrier film (not shown) is formed on the inner surface of the contact hole, a contact 81 containing W is formed in the contact hole.

Next, an a-Si layer 82 is formed on the interlayer dielectric film 80 and the contact 81. After that, a resist 85 is formed into a desired pattern on the a-Si layer 82. The desired pattern is the same as an interconnection pattern to be formed later. For this reason, the resist 85 is formed above the contact 81 so that the interconnection pattern is connected to the contact 81.

The a-Si layer 82 is partially selectively doped with an impurity by uniform ion implantation in a direction perpendicular to the surface of the semiconductor substrate 10. An impurity region 83 with the impurity diffused and a non-impurity region 84 having no impurity diffused are thus formed in the a-Si layer 82. More specifically, the impurity region 83 is formed in a region that is not covered with the resist 85. The non-impurity region 84 is formed under the resist 85 (in a region that is covered with the resist 85). The impurity to dope at this time is, for example, oxygen (0).

As shown in FIG. 59, after the resist 85 is removed, a metal layer 88 is formed on the a-Si layer 82 by, for example, PVD such as sputtering. That is, the metal layer 88 is formed on the impurity region 83 and the non-impurity region 84. The metal layer 88 contains a low-volatile metal material, for example, at least one of Ag and Cu. The metal layer 88 may contain Ag₂S or Cu₂S.

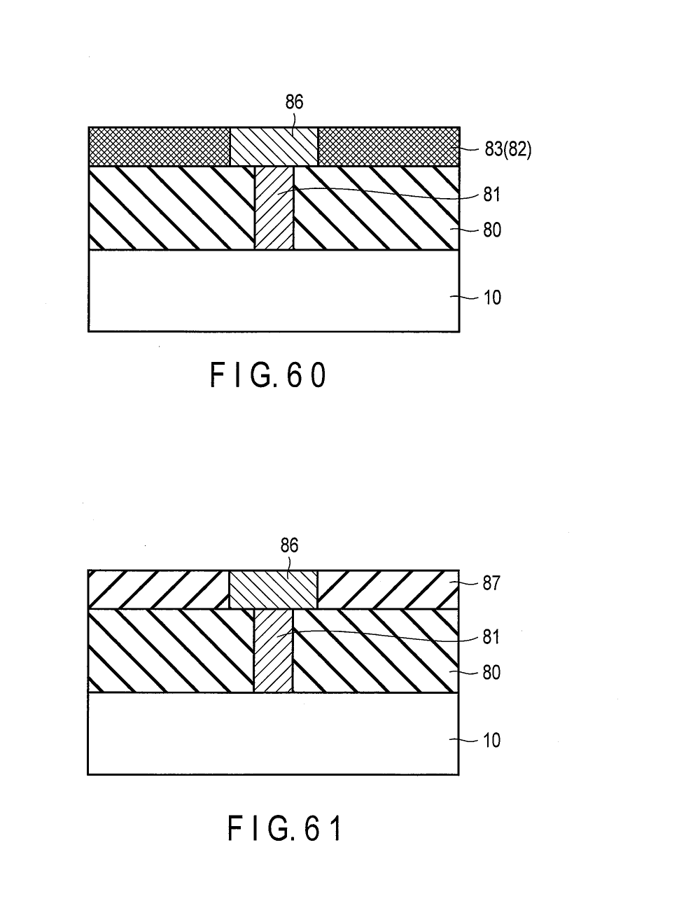

As shown in FIG. 60, the metal layer 88 is annealed. When the metal layer 88 contains Ag, this annealing is performed at a temperature of, for example, 350° C. (inclusive) to 500° C. (inclusive), and preferably, about 400° C. for 1 hr. The non-impurity region 84 is thus impregnated with the metal material contained in the metal layer 88 so that an interconnection 86 is formed in the a-Si layer 82. For this reason, the interconnection 86 contains Si and the metal material contained in the metal layer 88. At this time, the annealing is appropriately adjusted to diffuse (impregnate) the metal material from the upper surface to the lower surface of the a-Si layer 82.

This allows to electrically connect the interconnection 86 to the contact 81. In addition, the interconnection 86 is not a silicide, as described above. At this time, the impurity region 83 is not impregnated with the metal material.

As shown in FIG. 61, the a-Si layer 82 (impurity region 83) is removed by, for example, RIE. After that, an interlayer dielectric film 87 containing, for example, SiO₂ is formed on the interlayer dielectric film 80 so as to bury the periphery of the interconnection 86.

In the above-described way, the interconnection structure according to the application example is formed.

Note that in place of the impurity region 83, a silicon oxide film may be formed on the a-Si layer 82 not to diffuse the metal material into the a-Si layer 82, as in the second embodiment. As in the third embodiment, an a-Si layer may be formed by the sidewall transfer technology and impregnated with the metal material.

Note that although the metal material hard to process is used as the electrodes of an ReRAM in the above-described embodiment and as an interconnection in the application example, the embodiment is not limited to this. The metal material may be used as the electrodes or interconnections of various memories.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, comprising:
forming a first layer containing Si on a semiconductor substrate;
forming an impurity region and a non-impurity region in the first layer by selectively diffusing an impurity into the first layer;
forming a second layer containing a metal material on the first layer; and
diffusing the metal material into the non-impurity region by annealing the second layer.

2. The method of claim 1, wherein the metal material includes one of Ag and Cu.

3. The method of claim 1, wherein the impurity includes O.

4. The method of claim 3, wherein a concentration of O is not less than 1.0×10²¹ [atoms/cm³].

5. The method of claim 4, wherein a film thickness of the non-impurity region is not less than 20 nm.

6. The method of claim 1, wherein diffusion of the impurity is performed by ion implantation.

7. The method of claim 1, wherein the annealing is performed at 350° C. (inclusive) to 500° C. (inclusive).

8. The method of claim 1, wherein the impurity includes C.

9. A method of manufacturing a semiconductor device, comprising:
forming a first layer containing Si on a semiconductor substrate;
forming a core member on the first layer;
forming a second layer containing Si on an entire surface;
forming a non-impurity region in the second layer on a side surface of the core member and an impurity region in the second layer on a surface other than the side surface of the core member by selectively diffusing an impurity into the second layer;
forming a third layer containing a metal material on the second layer; and
diffusing the metal material into the non-impurity region by annealing the third layer.

10. The method of claim 9, wherein the metal material includes one of Ag and Cu.

11. The method of claim 9, wherein the impurity includes O.

12. The method of claim 11, wherein a concentration of O is not less than 1.0×10²¹ [atoms/cm³].

13. The method of claim 12, wherein a film thickness of the non-impurity region is not less than 20 nm.

14. The method of claim 9, wherein diffusion of the impurity is performed by ion implantation in a vertical direction.

15. The method of claim 9, wherein the annealing is performed at 350° C. (inclusive) to 500° C. (inclusive).

16. The method of claim 9, wherein the impurity includes C.

17. The method of claim 9, wherein a film thickness of the second layer is ½ a width of the core member.

18. A method of manufacturing a semiconductor device, comprising:
forming a first layer containing Si on a semiconductor substrate;
selectively forming a silicon oxide film on the first layer;
forming a second layer containing a metal material on an entire surface; and
diffusing the metal material into a region of the first layer in contact with the second layer by annealing the second layer.

19. The method of claim 18, wherein the metal material includes one of Ag and Cu.

20. The method of claim 18, wherein the annealing is performed at 350° C. (inclusive) to 500° C. (inclusive).
